(19) United States
(12) Patent Application Publication
(10) Pub. No.: US 2023/0389378 A1
(43) Pub. Date: Nov. 30, 2023

(54) DISPLAY DEVICE

(71) Applicant: Samsung Display Co., LTD., Yongin-si (KR)

(72) Inventors: Hyeon Bum LEE, Yongin-si (KR); Jun Hee LEE, Yongin-si (KR)

(21) Appl. No.: 18/189,948

(22) Filed: Mar. 24, 2023

(30) Foreign Application Priority Data
May 27, 2022 (KR) 10-2022-0065196

(51) Int. Cl. H10K 59/131; H10K 59/35; G09G 3/3233

(52) U.S. Cl. CPC H10K 59/131; H10K 59/35; G09G 3/3233; H10K 59/40

(57) ABSTRACT

A display device includes: a first emission area comprising a first light emitting element; a first driving transistor configured to provide a driving current to the first light emitting element and having a first driving channel containing a first material; a first transistor connected to the first driving transistor and having a first channel; a second transistor connected to the first driving transistor and the first transistor and having a second channel; a first data conductive layer comprising a connection electrode connected to the first transistor; and a second data conductive layer comprising a first data line connected to the second transistor and a first driving voltage line connected to the first transistor through the connection electrode, wherein the connection electrode overlaps the first emission area, and wherein the first data line overlaps the connection electrode and does not overlap the first emission area.

### CROSS-REFERENCE TO RELATED APPLICATION

The present application claims priority from to and the benefit of Korean Patent Application No. 10-2022-0065196 filed on May 27, 2022 in the Korean Intellectual Property Office, the entire content of which is incorporated herein by reference.

### BACKGROUND

### 1. Field

Aspects of some embodiments of the present disclosure relate to a display device and a semiconductor device.

### 2. Description of the Related Art

The importance of display devices has steadily increased with the development of multimedia technology. Accordingly, various types of display devices such as a liquid crystal display (LCD) device, an organic light emitting display (OLED) device and the like have been used.

As a method of improving the contrast of the OLED device without using a polarizing film, a method of reducing external light reflection may include forming a color filter and a light blocking portion as an encapsulation layer of the OLED device. The light blocking portion may include a plurality of openings corresponding to a plurality of pixels, and the color filter may be arranged to overlap the plurality of openings. The OLED device may be slimmed down because it may not use a polarizing film.

The above information disclosed in this Background section is only for enhancement of understanding of the background and therefore the information discussed in this Background section does not necessarily constitute prior art.

### SUMMARY

Aspects of the disclosure provide a display device in which a dummy line located under a light emitting layer is removed to prevent or reduce a step caused by the dummy line located under the light emitting layer and improve a flatness of the lower portion of the light emitting layer.

However, characteristics of embodiments according to the present disclosure are not restricted to those specifically set forth herein. The above and other aspects of the disclosure will become more apparent to one of ordinary skill in the art to which the disclosure pertains by referencing the detailed description of the disclosure given below.

According to some embodiments of the disclosure, a display device comprises a first emission area comprising a first light emitting element, a first driving transistor configured to provide a driving current to the first light emitting element and having a first driving channel containing a first material, a first transistor connected to the first driving transistor and having a first channel, a second transistor connected to the first driving transistor and the first transistor and having a second channel, a first data conductive layer comprising a connection electrode connected to the first transistor, and a second data conductive layer comprising a first data line connected to the second transistor and a first driving voltage line connected to the first transistor through the connection electrode, wherein the connection electrode overlaps the first emission area, and wherein the first data line overlaps the connection electrode and does not overlap the first emission area.

According to some embodiments, wherein the first data line and the first driving voltage line may extend in a first direction, and wherein the first data line and the first driving voltage line may be spaced apart from each other in a second direction crossing the first direction.

According to some embodiments, a display device may further comprise a second emission area spaced apart from the first emission area in a third direction crossing the first and second directions, and comprising a second light emitting element, wherein the first driving voltage line may not overlap the first emission area, and wherein the first driving voltage line may overlap the second emission area.

According to some embodiments, a display device may further comprise a third transistor connected to the first driving transistor and having a third channel containing a second material different from the first material, wherein the third transistor may overlap the second emission area.

According to some embodiments, wherein the first material may contain polysilicon, wherein the second material may contain an oxide semiconductor, wherein the third transistor may be located on a different layer from the first driving transistor, the first transistor, and the second transistor, and wherein the third transistor may not overlap the first emission area.

According to some embodiments, a display device may further comprise a third emission area spaced apart from the first emission area in the first direction and comprising a third light emitting element, a second driving transistor configured to provide a driving current to the third light emitting element and having a second driving channel containing the first material, and a fourth transistor connected to the second driving transistor and having a fourth channel, wherein the second data conductive layer may further comprise a second data line connected to the fourth transistor, wherein the second data line may extend in the first direction, wherein the second data line may be spaced apart from the first data line in the second direction with the first emission area interposed therebetween, and wherein the second data line may not overlap the first emission area.

According to some embodiments, wherein the first light emitting element emits green light, the second light emitting element emits red light, and the third light emitting element emits blue light.

According to some embodiments, wherein the first light emitting element emits red light or blue light, and the second light emitting element and the third light emitting element emit green light.

According to some embodiments, wherein the connection electrode may comprise a first portion having a larger size than the first emission area and a second portion protruding from the first portion and having a smaller size than the first portion, wherein the first portion of the connection electrode completely may overlap the first emission area in a plan view, and wherein the second portion of the connection electrode may not overlap the first emission area.

According to some embodiments, wherein the first driving voltage line may comprise a first portion having a larger size than the second emission area and a second portion protruding from the first portion and having a smaller size than the first portion, wherein the first portion of the first driving voltage line may completely overlap the second emission area in a plan view, and wherein the second portion of the first driving voltage line may not overlap the second emission area.

According to some embodiments, wherein the first portion of the connection electrode and the first portion of the first driving voltage line may have a plate shape.

According to some embodiments, wherein the first data line may comprise a first portion overlapping the connection electrode and a second portion not overlapping the connection electrode, and wherein the first portion of the first data line may comprise a curve.

According to some embodiments, wherein the second data line may comprise a first portion overlapping the connection electrode and a second portion not overlapping the connection electrode, and wherein at least one of the first portion of the first data line or the first portion of the second data line may comprise a curve.

According to some embodiments, a display device may further comprise a sensing device which is between the second portion of the first data line and the second portion of the second data line, and does not overlap the first data line and the second data line, wherein the sensing device may not overlap the first emission area, the second emission area, and the third emission area.

According to some embodiments, wherein the sensing device may be between the first emission area and the third emission area.

According to some embodiments of the disclosure, a display device comprises a substrate, a first transistor on the substrate, and comprising a first semiconductor layer containing a first material and a first gate electrode on the first semiconductor layer, a first insulating layer between the first semiconductor layer and the first gate electrode, and covering the first semiconductor layer, a second insulating layer on the first gate electrode, and covering the first gate electrode, a first data conductive layer on the second insulating layer, and comprising a connection electrode connected to the first transistor, a first via insulating layer on the first data conductive layer, and covering the connection electrode, a second data conductive layer on the first via insulating layer, and comprising a data line to which data voltages are applied and a driving voltage line connected to the first transistor by the connection electrode, a second via insulating layer on the second data conductive layer, and covering the second data conductive layer, and a light emitting element layer on the second via insulating layer, and comprising a first light emitting element and a first emission area defined by a first opening of a pixel defining layer on the first light emitting element, wherein the connection electrode overlaps the first emission area and the pixel defining layer, and wherein the data line and the driving voltage line overlap the connection electrode, and do not overlap the first emission area.

According to some embodiments, a display device may further comprise a third insulating layer on the second insulating layer, a second semiconductor layer between the second insulating layer and the third insulating layer, and containing a second material different from the first material, a fourth insulating layer on the second semiconductor layer, and covering the second semiconductor layer, and a second transistor comprising an upper gate electrode on the fourth insulating layer and a lower gate electrode on the second insulating layer with the second semiconductor layer interposed therebetween, wherein the light emitting element layer may further comprise a second light emitting element spaced apart from the first light emitting element and a second emission area defined by a second opening of a pixel defining layer on the second light emitting element, and wherein the driving voltage line may overlap the second emission area.

According to some embodiments, wherein the first material contains polysilicon, and the second material may contain an oxide semiconductor.

According to some embodiments, a display device may further comprise a touch sensing unit on the pixel defining layer surrounding the first emission area and the second emission area, and comprising a touch insulating layer and a touch electrode, and a light blocking member on the touch sensing unit and overlapping the pixel defining layer, wherein the light blocking member may overlap the data line and the driving voltage line.

According to some embodiments, a display device may further comprise a first color filter and a second color filter on the light blocking member, wherein the first color filter may overlap the first emission area, and wherein the second color filter may overlap the second emission area.

In a display device according to some embodiments, the flatness of the lower portion of the light emitting layer can be improved by removing the dummy line under the light emitting layer. Accordingly, it may be possible to improve the reliability of the display device by reducing reflective color bands of green, magenta and the like, which are generated around the plurality of opening due to light that is emitted from the light emitting layer and is diffusely reflected by the step under the light emitting layer.

However, the characteristics of embodiments according to the present disclosure are not limited to the aforementioned characteristics, and various other characteristics are included in the disclosure.

### BRIEF DESCRIPTION OF THE DRAWINGS

The above and other aspects and features of the disclosure will become more apparent by describing in more detail aspects of some embodiments thereof with reference to the attached drawings, in which:

FIG. 1 is a perspective view showing a display device according to some embodiments;

FIG. 2 is a cross-sectional view illustrating a display device according to some embodiments;

FIG. 3 is a plan view illustrating a display unit of a display device according to some embodiments;

FIG. 4 is a plan view illustrating a touch sensing unit of a display device according to some embodiments;

FIG. 5 is an enlarged view of the area A of FIG. 4;

FIG. 6 is a circuit diagram illustrating a display unit according to some embodiments;

FIG. 7 is a plan view illustrating aspects of a pixel according to some embodiments;

FIG. 8 is a plan view illustrating a lower metal layer, a first semiconductor layer, a first gate layer, a second gate layer, and a second semiconductor layer of FIG. 7;

FIG. 9 is a plan view illustrating the first semiconductor layer, the first gate layer, the second gate layer, the second semiconductor layer, and a third gate layer of FIG. 7;

FIG. 10 is a plan view illustrating a lower metal layer, a first semiconductor layer, a first gate layer, a second gate layer, a second semiconductor layer, a third gate layer, and a first data conductive layer that are sequentially stacked;

FIG. 11 is a diagram illustrating a lower metal layer, the first semiconductor layer ACT1, the first gate layer GTL1, the second gate layer GTL2, the second semiconductor layer ACT2, the third gate layer GTL3, the first data conductive layer DTL1, the second data conductive layer DTL2, and light emitting element that are sequentially stacked;

FIG. 12 is a plan view illustrating a first data conductive layer, a second data conductive layer, and an emission area of a plurality of pixels according to some embodiments;

FIG. 13 is a plan view illustrating a first data conductive layer, a second data conductive layer, and an emission area of a plurality of pixels according to some embodiments;

FIG. 14 is a plan view illustrating a first data conductive layer, a second data conductive layer, and an emission area of a plurality of pixels according to some embodiments;

FIG. 15 is a cross-sectional view illustrating an example taken along the line I-I′ of FIG. 11;

FIG. 16 is a cross-sectional view illustrating an example taken along the line II-II′ of FIG. 11;

FIG. 17 is an image of a display device in which a reflective color band is generated when a second data conductive layer is located under an emission area; and

FIG. 18 is an image of a display device in which a reflective color band is generated when a second data conductive layer is not located under an emission area.

### DETAILED DESCRIPTION

Aspects of some embodiments of the present invention will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Features of each of various embodiments of the disclosure may be partially or entirely combined with each other and may technically variously interwork with each other, and respective embodiments may be implemented independently of each other or may be implemented together in association with each other.

Hereinafter, embodiments of the disclosure will be described with reference to the attached drawings.

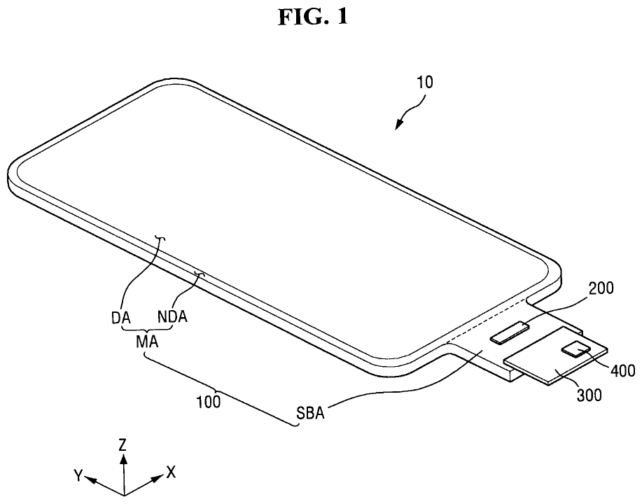

FIG. 1 is a perspective view showing a display device according to some embodiments.

Referring to FIG. 1, a display device 10 may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like.

For example, the display device 10 may be applied as a display unit of a television, a laptop, a monitor, a billboard, or an Internet-of-Things (IoT) device. For another example, the display device 10 may be applied to wearable devices such as a smart watch, a watch phone, a glasses type display, or a head mounted display (HMD). The display device 10 may have a planar shape similar to a quadrilateral shape. For example, the display device 10 may have a shape similar to a quadrilateral shape, in a plan view, having short sides in an X-axis direction and long sides in a Y-axis direction. The corner where the short side in the X-axis direction and the long side in the Y-axis direction meet may be rounded to have a curvature (e.g., a set or predetermined curvature) or may be right-angled. The planar shape of the display device 10 is not limited to a quadrilateral shape, and may be formed in a shape similar to another polygonal shape, a circular shape, or elliptical shape.

The display device 10 may include the display panel 100, the display driver 200, the circuit board 300, and the touch driver 400.

The display panel 100 may include a main region MA and a sub-region SBA.

The main region MA may include the display area DA including pixels displaying an image and the non-display area NDA arranged around the display area DA. The display area DA may emit light from a plurality of emission areas or a plurality of opening areas. For example, the display panel 100 may include a pixel circuit including switching elements, a pixel defining layer defining an emission area or an opening area, and a self-light emitting element.

For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but embodiments according to the present disclosure are not limited thereto.

The non-display area NDA may be an area outside the display area DA. The non-display area NDA may be defined as an edge area of the main region MA of the display panel 100. The non-display area NDA may include a gate driver that supplies gate signals to the gate lines, and fan-out lines that connect the display driver 200 to the display area DA.

The sub-region SBA may extend from one side of the main region MA. The sub-region SBA may include a flexible material which can be bent, folded or rolled. For example, when the sub-region SBA is bent, the sub-region SBA may overlap the main region MA in a thickness direction (Z-axis direction). The sub-region SBA may include the display driver 200 and the pad unit connected to the circuit board 300. Optionally, the sub-region SBA may be omitted, and the display driver 200 and the pad unit may be arranged in the non-display area NDA.

The display driver 200 may output signals and voltages for driving the display panel 100. The display driver 200 may supply data voltages to data lines. The display driver 200 may supply a power voltage to the power line and may supply a gate control signal to the gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be located in the sub-region SBA, and may overlap the main region MA in the thickness direction (Z-axis direction) by bending of the sub-region SBA. For another example, the display driver 200 may be mounted on the circuit board 300.

The circuit board 300 may be attached to the pad unit of the display panel 100 by using an anisotropic conductive film (ACF). Lead lines of the circuit board 300 may be electrically connected to a pad unit of the display panel 100. The circuit board 300 may be a flexible printed circuit board, a printed circuit board, or a flexible film such as a chip on film.

A touch driver 400 may be mounted on the circuit board 300. The touch driver 400 may be connected to a touch sensing unit of the display panel 100. The touch driver 400 may supply a touch driving signal to a plurality of touch electrodes of the touch sensing unit and may sense an amount of change in capacitance between the plurality of touch electrodes. For example, the touch driving signal may be a pulse signal having a frequency (e.g., a set or predetermined frequency). The touch driver 400 may calculate whether an input is made and input coordinates based on an amount of change in capacitance between the plurality of touch electrodes. The touch driver 400 may be formed of an integrated circuit (IC).

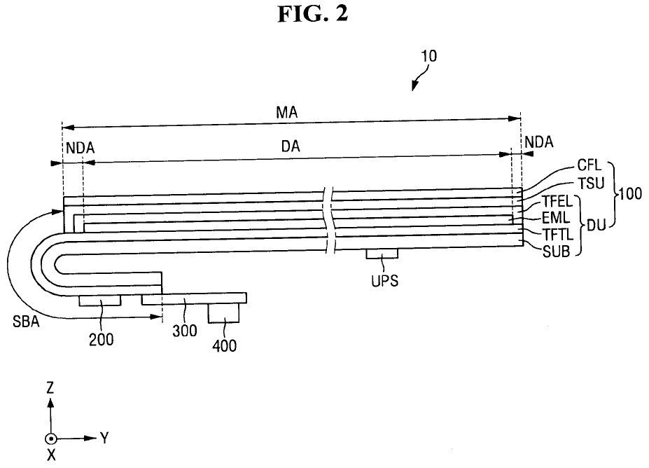

FIG. 2 is a cross-sectional view illustrating a display device according to some embodiments.

Referring to FIG. 2, the display panel 100 may include a display unit DU, a touch sensing unit TSU, and a color filter layer CFL. The display unit DU may include the substrate SUB, the thin film transistor layer TFTL, the light emitting element layer EML, and the encapsulation layer TFEL.

The substrate SUB may be a base substrate or a base member. The substrate SUB may be a flexible substrate which can be bent, folded or rolled. For example, the substrate SUB may include a polymer resin such as polyimide (PI), but embodiments according to the present disclosure are not limited thereto. In some embodiments, the substrate SUB may include a glass material or a metal material.

The thin film transistor layer TFTL may be located on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines that connect the display driver 200 to the data lines, and lead lines that connect the display driver 200 to the pad unit. Each of the thin film transistors may include a semiconductor region, a source electrode, a drain electrode, and a gate electrode. For example, when the gate driver is formed on one side of the non-display area NDA of the display panel 100, the gate driver may include thin film transistors.

The thin film transistor layer TFTL may be located in the display area DA, the non-display area NDA, and the sub-region SBA. Thin film transistors, gate lines, data lines, and power lines of each of the pixels of the thin film transistor layer TFTL may be located in the display area DA. Gate control lines and fan-out lines of the thin film transistor layer TFTL may be located in the non-display area NDA. The lead lines of the thin film transistor layer TFTL may be located in the sub-region SBA.

The light emitting element layer EML may be located on the thin film transistor layer TFTL. The light emitting element layer EML may include a plurality of light emitting elements in which a first electrode, a light emitting layer, and a second electrode are sequentially stacked to emit light, and a pixel defining layer defining pixels. The plurality of light emitting elements of the light emitting element layer EML may be located in the display area DA.

For example, the light emitting layer may be an organic light emitting layer including an organic material. The light emitting layer may include a hole transporting layer, an organic light emitting layer, and an electron transporting layer. When the first electrode receives a voltage (e.g., a set or predetermined voltage) through the thin film transistor of the thin film transistor layer TFTL and the second electrode receives the cathode voltage, holes and electrons may be transferred to the organic light emitting layer through the hole transporting layer and the electron transporting layer, respectively and may be combined with each other to emit light in the organic light emitting layer. For example, the first electrode may be an anode electrode, and the second electrode may be a cathode electrode, but embodiments according to the present disclosure are not limited thereto. In some embodiments, the plurality of light emitting elements may include a quantum dot light emitting diode including a quantum dot light emitting layer, an inorganic light emitting diode including an inorganic semiconductor, or a micro light emitting diode.

The encapsulation layer TFEL may cover the top surface and the side surface of the light emitting element layer EML, and may protect the light emitting element layer EML. The encapsulation layer TFEL may include at least one inorganic layer and at least one organic layer for encapsulating the light emitting element layer EML.

The touch sensing unit TSU may be located on the encapsulation layer TFEL. The touch sensing unit TSU may include a plurality of touch electrodes for sensing a user's touch in a capacitive manner, and touch lines connecting the plurality of touch electrodes to the touch driver 400. For example, the touch sensing unit TSU may sense the user's touch by using a mutual capacitance method or a self-capacitance method. In some embodiments, the touch sensing unit TSU may be located on a separate substrate located on the display unit DU. In this case, the substrate supporting the touch sensing unit TSU may be a base member that encapsulates the display unit DU.

The plurality of touch electrodes of the touch sensing unit TSU may be located in a touch sensor area overlapping the display area DA. The touch lines of the touch sensing unit TSU may be located in a touch peripheral area that overlaps the non-display area NDA.

The color filter layer CFL may be located on the touch sensing unit TSU. The color filter layer CFL may include a plurality of color filters respectively corresponding to the plurality of emission areas. Each of the color filters may selectively transmit light of a specific wavelength and may block or absorb light of a different wavelength. The color filter layer CFL may absorb a part of light coming from the outside of the display device 10 to reduce reflected light due to external light. Accordingly, the color filter layer CFL may prevent or reduce color distortion caused by reflection of the external light.

The sub-region SBA of the display panel 100 may extend from one side of the main region MA. The sub-region SBA may include a flexible material which can be bent, folded or rolled. For example, when the sub-region SBA is bent, the sub-region SBA may overlap the main region MA in a thickness direction (Z-axis direction). The sub-region SBA may include the display driver 200 and the pad unit electrically connected to the circuit board 300.

A sensing device UPS may be located under the substrate SUB. A main processor may control the display device 10 according to sensor signals inputted from the sensing device UPS. The sensing device UPS may be any one of a proximity sensor, an illuminance sensor, an iris sensor, and a camera sensor.

The proximity sensor may detect whether an object is close to the top surface of the display device 10. For example, the proximity sensor may include a light source that outputs light and a light receiver that receives light reflected by an object. The proximity sensor may determine whether or not there is an object located close to the top surface of the display device 10 according to the amount of light reflected by the object.

The illuminance sensor may detect the brightness of the top surface of the display device 10. The illuminance sensor may include a resistor whose resistance value changes according to the brightness of the incident light. The illuminance sensor may determine the brightness of the top surface of the display device 10 according to the resistance value of the resistor.

The iris sensor may detect whether the image of the user's iris is the same as the iris image previously stored in the memory. The iris sensor may generate and output an iris sensor signal to the main processor according to whether the user's iris image is the same as the iris image previously stored in the memory.

The camera sensor may process an image frame of a still image or video obtained by the image sensor and output it to the main processor. For example, the camera sensor may be a CMOS image sensor or a CCD sensor, but embodiments according to the present disclosure are not limited thereto.

The sensing device UPS is not limited thereto, and may further include a fingerprint scanner, a strobe, an optical sensor, a proximity sensor, an indicator, a solar panel, or the like.

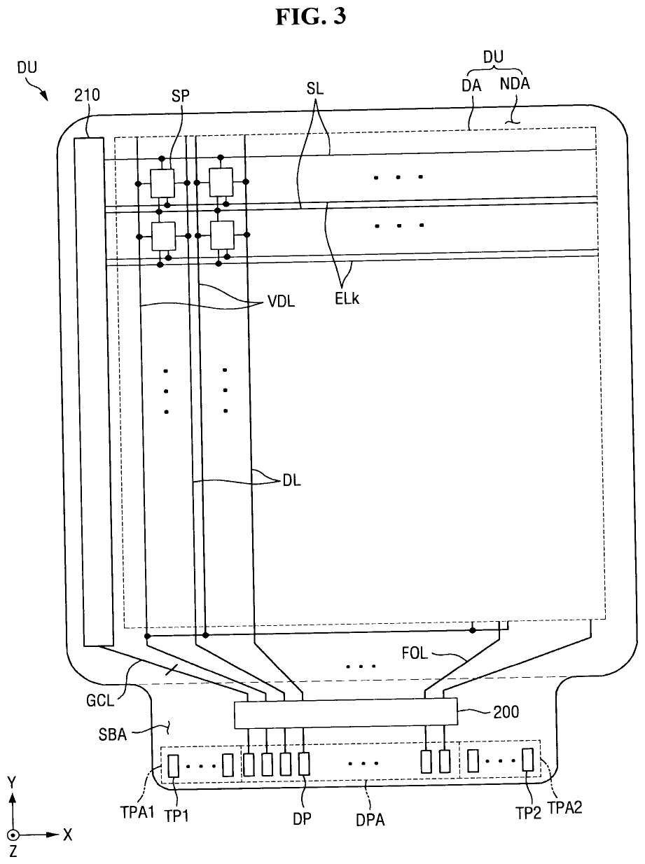

FIG. 3 is a plan view illustrating a display unit of a display device according to some embodiments.

Referring to FIG. 3, the display unit DU may include the display area DA and the non-display area NDA.

The display area DA, which is an area for displaying an image, may be defined as the central area of the display panel 100. The display area DA may include a plurality of pixels SP, a plurality of scan lines SL, a plurality of data lines DL, a plurality of emission control lines ELk, and a plurality of driving voltage lines VDL. Each of the plurality of pixels SP may be defined as the smallest unit that outputs light.

Each of the pixels SP may be connected to at least one of the scan lines SL, at least one of the data lines DL, at least one of the emission control lines ELk, and the driving voltage line VDL. FIG. 3 illustrates that each of the pixels SP is connected to two scan lines SL, one data line DL, one emission control line ELK and the driving voltage line VDL, but embodiments according to the present disclosure are not limited thereto. In some embodiments, each of the plurality of sub-pixels SP may be connected to four scan lines SL rather than two scan lines SL.

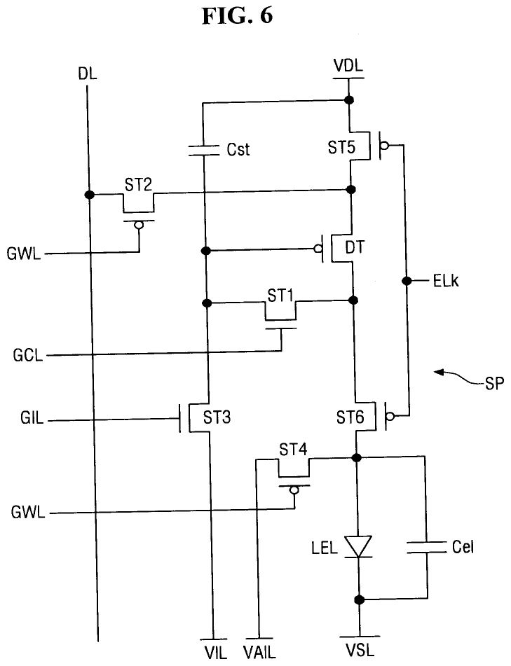

The scan line SL may be any one of a write scan line GWL and an initialization scan line GIL, which will be described later with reference to FIG. 6. However, embodiments according to the present disclosure are not limited thereto. Further, the plurality of scan lines SL may supply a gate signal received from a scan driver 210 to the plurality of pixels SP. The plurality of scan lines SL may extend in the X-axis direction and may be spaced apart from each other in the Y-axis direction that crosses the X-axis direction.

The plurality of data lines DL may supply the data voltages received from the display driver 200 to the plurality of pixels SP. The plurality of data lines DL may extend in the Y-axis direction and may be spaced apart from each other in the X-axis direction.

The plurality of driving voltage lines VDL may supply the power voltage received from the display driver 200 to the plurality of pixels SP. The power voltage may be at least one of a driving voltage, an initialization voltage, a reference voltage, or a low potential voltage. The plurality of driving voltage lines VDL may extend in the Y-axis direction and may be spaced apart from each other in the X-axis direction.

The non-display area NDA may surround the display area DA. The non-display area NDA may include the scan driver 210, fan-out lines FOL, and scan control lines GCL. The scan driver 210 may generate a plurality of scan signals based on a scan control signal, and may sequentially supply the plurality of scan signals to the plurality of scan lines SL according to a set order.

The fan-out lines FOL may extend from the display driver 200 to the display area DA. The fan-out lines FOL may supply the data voltage received from the display driver 200 to the plurality of data lines DL.

The scan control line GCL may extend from the display driver 200 to the scan driver 210. The scan control line GCL may supply the scan control signal received from the display driver 200 to the scan driver 210.

The sub-region SBA may include the display driver 200, a display pad area DPA, and first and second touch pad areas TPA1 and TPA2.

The display driver 200 may output signals and voltages for driving the display panel 100 to the fan-out lines FOL. The display driver 200 may supply a data voltage to the data line DL through the fan-out lines FOL. The data voltage may be supplied to the plurality of pixels SP to determine the luminance of the plurality of pixels SP. The display driver 200 may supply the scan control signal to the scan driver 210 through the scan control line GCL.

The display pad area DPA, the first touch pad area TPA1, and the second touch pad area TPA2 may be located at the edge of the sub-region SBA. The display pad area DPA, the first touch pad area TPA1, and the second touch pad area TPA2 may be electrically connected to the circuit board 300 by using a low-resistance high-reliability material such as an anisotropic conductive film or self assembly anisotropic conductive paste (SAP).

The display pad area DPA may include a plurality of display pad units DP. The plurality of display pad units DP may be connected to a graphic system through the circuit board 300. The plurality of display pad units DP may be connected to the circuit board 300 to receive digital video data, and may supply the digital video data to the display driver 200.

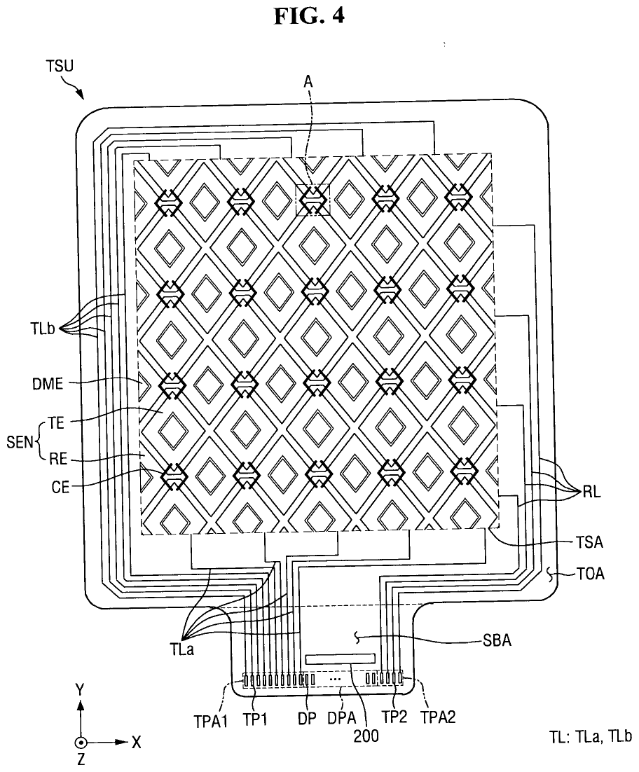

FIG. 4 is a plan view illustrating a touch sensing unit of a display device according to some embodiments.

Referring to FIG. 4, the touch sensing unit TSU may include a touch sensor area TSA for sensing a user's touch, and a touch peripheral area TOA arranged around the touch sensor area TSA. The touch sensor area TSA may overlap the display area DA of the display unit DU, and the touch peripheral area TOA may overlap the non-display area NDA of the display unit DU.

The touch sensor area TSA may include a plurality of touch electrodes SEN and a plurality of dummy electrodes DME. The plurality of touch electrodes SEN may form mutual capacitance or self-capacitance to sense a touch of an object or a person. The plurality of touch electrodes SEN may include a plurality of driving electrodes TE and a plurality of sensing electrodes RE.

The plurality of driving electrodes TE may be arranged in the X-axis direction and the Y-axis direction. The plurality of driving electrodes TE may be spaced apart from each other in the X-axis direction and the Y-axis direction. The driving electrodes TE adjacent in the Y-axis direction may be electrically connected through a bridge electrode CE.

The plurality of driving electrodes TE may be connected to a first touch pad unit TP1 through a driving line TL. The driving line TL may include a lower driving line TLa and an upper driving line TLb. For example, the driving electrodes TE located under the touch sensor area TSA may be connected to the first touch pad unit TP1 through the lower driving line TLa, and the driving electrodes TE located on the upper side of the touch sensor area TSA may be connected to the first touch pad unit TP1 through the upper driving line TLb. The lower driving line TLa may extend to the first touch pad unit TP1 through the lower side of the touch peripheral area TOA. The upper driving line TLb may extend to the first touch pad unit TP1 through the upper side, the left side, and the lower side of the touch peripheral area TOA. The first touch pad unit TP1 may be connected to the touch driver 400 through the circuit board 300.

The bridge electrode CE may be bent at least once. For example, the bridge electrode CE may have an angle bracket shape (“<” or “>”), but the planar shape of the bridge electrode CE is not limited thereto. The driving electrodes TE adjacent to each other in the Y-axis direction may be connected by a plurality of bridge electrodes CE, and although any one of the bridge electrodes CE is disconnected, the driving electrodes TE may be relatively stably connected through the remaining bridge electrode CE. The driving electrodes TE adjacent to each other may be connected by two bridge electrodes CE, but the number of bridge electrodes CE is not limited thereto.

The bridge electrode CE may be located on a different layer from the plurality of driving electrodes TE and the plurality of sensing electrodes RE. The sensing electrodes RE adjacent to each other in the X-axis direction may be electrically connected through a connection portion located on the same layer as the plurality of driving electrodes TE or the plurality of sensing electrodes RE, and the driving electrodes TE adjacent in the Y-axis direction may be electrically connected through the bridge electrode CE located on a different layer from the plurality of driving electrodes TE or the plurality of sensing electrodes RE. Accordingly, although the bridge electrode CE overlaps the plurality of sensing electrodes RE in the Z-axis direction, the plurality of driving electrodes TE and the plurality of sensing electrodes RE may be insulated from each other. Mutual capacitance may be formed between the driving electrode TE and the sensing electrode RE.

The plurality of sensing electrodes RE may extend in the X-axis direction and may be spaced apart from each other in the Y-axis direction. The plurality of sensing electrodes RE may be arranged in the X-axis direction and the Y-axis direction, and the sensing electrodes RE adjacent in the X-axis direction may be electrically connected through a connection portion.

The plurality of sensing electrodes RE may be connected to a second touch pad unit TP2 through a sensing line RL. For example, the sensing electrodes RE located on the right side of the touch sensor area TSA may be connected to the second touch pad unit TP2 through the sensing line RL. The sensing line RL may extend to the second touch pad unit TP2 through the right side and the lower side of the touch peripheral area TOA. The second touch pad unit TP2 may be connected to the touch driver 400 through the circuit board 300.

Each of the plurality of dummy electrodes DME may be surrounded by the driving electrode TE or the sensing electrode RE. Each of the dummy electrodes DME may be insulated by being spaced apart from the driving electrode TE or the sensing electrode RE. Accordingly, the dummy electrode DME may be electrically floating.

The display pad area DPA, the first touch pad area TPA1, and the second touch pad area TPA2 may be located at the edge of the sub-region SBA. The display pad area DPA, the first touch pad area TPA1, and the second touch pad area TPA2 may be electrically connected to the circuit board 300 by using a low-resistance high-reliability material such as an anisotropic conductive film or self-assembly anisotropic conductive paste (SAP).

The first touch pad area TPA1 may be located on one side of the display pad area DPA, and may include a plurality of first touch pad units TP1. The plurality of first touch pad units TP1 may be electrically connected to the touch driver 400 located on the circuit board 300. The plurality of first touch pad units TP1 may supply a touch driving signal to the plurality of driving electrodes TE through a plurality of driving lines TL.

The second touch pad area TPA2 may be located on the other side of the display pad area DPA, and may include a plurality of second touch pad units TP2. The plurality of second touch pad units TP2 may be electrically connected to the touch driver 400 located on the circuit board 300. The touch driver 400 may receive a touch sensing signal through a plurality of sensing lines RL connected to the plurality of second touch pad units TP2, and may sense a change in mutual capacitance between the driving electrode TE and the sensing electrode RE.

In some embodiments, the touch driver 400 may supply a touch driving signal to each of the plurality of driving electrodes TE and the plurality of sensing electrodes RE, and may receive a touch sensing signal from each of the plurality of driving electrodes TE and the plurality of sensing electrodes RE. The touch driver 400 may sense an amount of change in electric charge of each of the plurality of driving electrodes TE and the plurality of sensing electrodes RE based on the touch sensing signal.

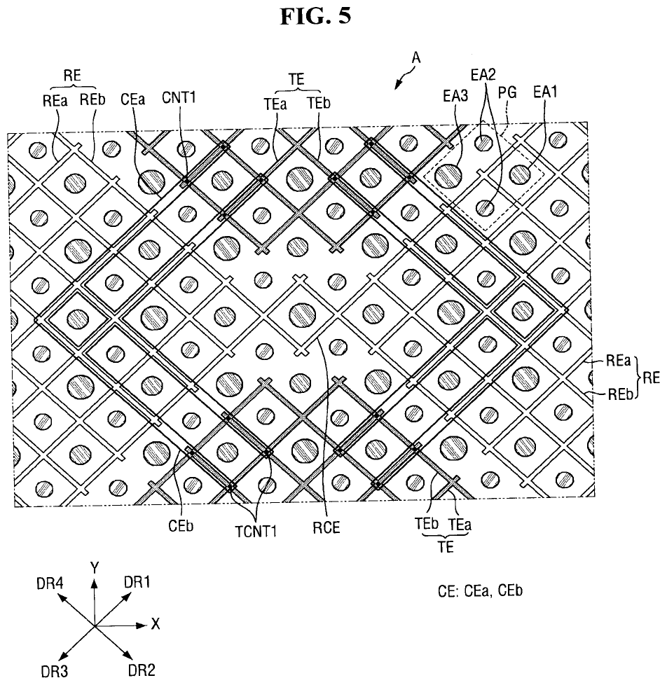

FIG. 5 is an enlarged view of the area A of FIG. 4.

Referring to FIG. 5, the plurality of driving electrodes TE, the plurality of sensing electrodes RE, and the plurality of dummy electrodes DME may be located on the same layer and may be spaced apart from each other.

The plurality of driving electrodes TE may be arranged in the X-axis direction and the Y-axis direction. The plurality of driving electrodes TE may be spaced apart from each other in the X-axis direction and the Y-axis direction. The driving electrodes TE adjacent in the Y-axis direction may be electrically connected through a bridge electrode CE.

The plurality of sensing electrodes RE may extend in the X-axis direction and may be spaced apart from each other in the Y-axis direction. The plurality of sensing electrodes RE may be arranged in the X-axis direction and the Y-axis direction, and the sensing electrodes RE adjacent in the X-axis direction may be electrically connected through a connection portion RCE. For example, the connection portion RCE of the sensing electrodes RE may be located within the shortest distance between the driving electrodes TE adjacent to each other.

The plurality of bridge electrodes CE may be located on a different layer from the driving electrode TE and the sensing electrode RE. The bridge electrode CE may include a first portion CEa and a second portion CEb. For example, the first portion CEa of the bridge electrode CE may be connected to the driving electrode TE located on one side through a first touch contact hole TCNT1 and extend in a third direction DR3. The second portion CEb of the bridge electrode CE may be bent from the first portion CEa in an area overlapping the sensing electrode RE to extend in a second direction DR2, and may be connected to the driving electrode TE located on the other side through the first touch contact hole TCNT1. Hereinafter, a first direction DR1 may be a direction between the X-axis direction and the Y-axis direction, a second direction DR2 may be a direction between the opposite direction of the Y-axis and the X-axis direction, a third direction DR3 may be an opposite direction of the first direction DR1, and a fourth direction DR4 may be an opposite direction of the second direction DR2. Accordingly, each of the plurality of bridge electrodes CE may electrically connect the adjacent driving electrodes TE in the Y-axis direction.

In some embodiments, the plurality of driving electrodes TE, the plurality of sensing electrodes RE, and the plurality of dummy electrodes DME may be formed in a planar mesh structure or a mesh structure. The plurality of driving electrodes TE, the plurality of sensing electrodes RE, and the plurality of dummy electrodes DME may surround each of first to third emission areas EA1, EA2, and EA3 of a pixel group PG in a plan view. Accordingly, the plurality of driving electrodes TE, the plurality of sensing electrodes RE, and the plurality of dummy electrodes DME may not overlap first to third emission areas EA1, EA2, and EA3. The plurality of bridge electrodes CE may also not overlap the first to third emission areas EA1, EA2, and EA3. Accordingly, the display device 10 may prevent or reduce instances of the luminance of light emitted from the first to third emission areas EA1, EA2, and EA3 being reduced by the touch sensing unit TSU.

Each of the plurality of driving electrodes TE may include a first portion TEa extending in the first direction DR1 and a second portion TEb extending in the second direction DR2. Each of the plurality of sensing electrodes RE may include a first portion REa extending in the first direction DR1 and a second portion REb extending in the second direction DR2.

The plurality of pixels may include first to third pixels, and each of the first to third pixels may include the first to third emission areas EA1, EA2, and EA3. For example, the first emission area EA1 may emit light of a first color or red light, the second emission area EA2 may emit light of a second color or green light, and the third emission area EA3 may emit light of a third color or blue light, but embodiments according to the present disclosure are not limited thereto.

One pixel group PG may represent white gray scale by including one first emission area EA1, two second emission areas EA2, and one third emission area EA3, but the configuration of the pixel group PG is not limited thereto. In some embodiments, the white gray scale may be represented by a combination of light emitted from one first emission area EA1, light emitted from two second emission areas EA2, and light emitted from one third emission area EA3.

The first to third emission areas EA1, EA2, and EA3 may be different in size from each other. For example, the size of the third emission area EA3 may be larger than that of the first emission area EA1, and the size of the first emission area EA1 may be larger than that of the second emission area EA2. However, embodiments according to the present disclosure are not limited thereto. In some embodiments, the sizes of the first to third emission areas EA1, EA2, and EA3 may be the same.

FIG. 5 illustrates that the first to third emission areas EA1, EA2, and EA3 have a circular shape in a plan view, but embodiments according to the present disclosure are not limited thereto. In some embodiments, the planar shape of the first to third emission areas EA1, EA2, and EA3 may be substantially octagonal. According to some embodiments, the planar shape of the first to third emission areas EA1, EA2, and EA3 may be a rhombus, other polygons, a polygon with rounded corners, or the like.

FIG. 6 is a circuit diagram illustrating a display unit according to some embodiments.

Referring to FIG. 6, the pixel SP may be connected to any two of the scan lines SL, any one of the emission control lines ELK and any one of the data lines DL. For example, the pixel SP may be connected to the write scan line GWL, the initialization scan line GIL, the scan control line GCL, the emission control line ELK and the data line DL.

The pixel SP may include a driving transistor DT, a light emitting element LEL, switch elements, and a capacitor Cst. The switching elements may include first to sixth transistors ST1, ST2, ST3, ST4, ST5 and ST6.

The driving transistor DT controls a source-drain current Isd (hereinafter, referred to as “driving current”) according to the data voltage applied to the gate electrode. The driving current Isd flowing through a channel of the driving transistor DT is proportional to a square of a difference between a gate-source voltage Vsg of the driving transistor DT and a threshold voltage (Isd=k′×(Vsg−Vth)²). Here, k′ is a proportional coefficient determined by a structure and physical characteristics of the driving transistor, Vsg is a source-gate voltage of the driving transistor, and Vth is a threshold voltage of the driving transistor.

The light emitting element LEL emits light by the driving current Ids. A light emission amount of the light emitting element LEL may be proportional to the driving current Ids.

The light emitting element LEL may be an organic light emitting diode including an anode electrode, a cathode electrode, and an organic light emitting layer located between the anode electrode and the cathode electrode. Alternatively, the light emitting element LEL may be an inorganic light emitting element including an anode electrode, a cathode electrode, and an inorganic semiconductor located between the anode electrode and the cathode electrode. Alternatively, the light emitting element LEL may be a quantum dot light emitting element including an anode electrode, a cathode electrode, and a quantum dot light emitting layer located between the anode electrode and the cathode electrode. Alternatively, the light emitting element LEL may be a micro light emitting diode.

The anode electrode of the light emitting element LEL may be connected to a first electrode of the fourth transistor ST4 and a second electrode of the sixth transistor ST6, and the cathode electrode thereof may be connected to a low potential line VSL. A parasitic capacitance Cel may be formed between the anode electrode and the cathode electrode of the light emitting element LEL.

The sixth transistor ST6 is turned on by the emission control signal of the emission control line ELk to connect the second electrode of the driving transistor DT to the anode electrode of the light emitting element LEL. The gate electrode of the sixth transistor ST6 is connected to the emission control line ELk, the first electrode thereof is connected to the second electrode of the driving transistor DT, and the second electrode thereof is connected to the anode electrode of the light emitting element LEL. When the sixth transistor ST6 is turned on, the driving current Isd may be supplied to the light emitting element LEL. For example, the first electrode of the sixth transistor ST6 may be a source electrode and the second electrode thereof may be a drain electrode, but embodiments according to the present disclosure are not limited thereto.

The first transistor ST1 may be turned on by a scan signal applied to the scan control line GCL to connect the second electrode of the driving transistor DT to the gate electrode of the driving transistor DT. A gate electrode of the first transistor ST1 may be connected to the scan control line GCL, and a second electrode of the first transistor ST1 may be connected to the gate electrode of the driving transistor DT, a first electrode of the third transistor ST3, and a first capacitor electrode of a first capacitor Cst. For example, a first electrode of the first transistor ST1 may be a drain electrode and the second electrode thereof may be a source electrode, but embodiments according to the present disclosure are not limited thereto.

The fourth transistor ST4 may be turned on by a scan signal of the write scan line GWL to connect a first initialization voltage line VAIL to a first electrode of the light emitting element LEL. The fourth transistor ST4 may be turned on based on the scan signal to discharge the first electrode of the light emitting element LEL to a first initialization voltage. A gate electrode of the fourth transistor ST4 may be connected to the write scan line GWL, a second electrode thereof may be connected to the first initialization voltage line VAIL, and the first electrode thereof may be connected to the first electrode of the light emitting element LEL and the second electrode of the sixth transistor ST6. For example, the first electrode of the fourth transistor ST4 may be a source electrode and the second electrode thereof may be a drain electrode, but embodiments according to the present disclosure are not limited thereto.

The second transistor ST2 may be turned on by the scan signal of the write scan line GWL to connect the data line DL to the first electrode of the driving transistor DT. A gate electrode of the second transistor ST2 may be connected to the write scan line GWL, a first electrode thereof may be connected to the data line DL, and a second electrode thereof may be connected to the first electrode of the driving transistor DT and a second electrode of the fifth transistor ST5. For example, the first electrode of the second transistor ST2 may be a source electrode and the second electrode thereof may be a drain electrode, but embodiments according to the present disclosure are not limited thereto.

The third transistor ST3 may be turned on by an initialization scan signal of the initialization scan line GIL to connect a second initialization voltage line VIL to the gate electrode of the driving transistor DT. The third transistor ST3 may be turned on based on the initialization scan signal to discharge the gate electrode of the driving transistor DT to a second initialization voltage. A gate electrode of the third transistor ST3 may be connected to the initialization scan line GIL, a second electrode thereof may be connected to the second initialization voltage line VIL, and the first electrode thereof may be connected to the gate electrode of the driving transistor DT, the second electrode of the first transistor ST1, and the first capacitor electrode of the first capacitor Cst. For example, the first electrode of the third transistor ST3 may be a drain electrode and the second electrode thereof may be a source electrode, but embodiments according to the present disclosure are not limited thereto.

The fifth transistor ST5 may be turned on by an emission control signal of the emission control line ELk to connect the driving voltage line VDL to the first electrode of the driving transistor DT. A gate electrode of the fifth transistor ST5 may be connected to the emission control line ELK a first electrode thereof may be connected to the driving voltage line VDL, and the second electrode thereof may be electrically connected to the first electrode of the driving transistor DT and the second electrode of the second transistor ST2. The first electrode of the fifth transistor ST5 may be a source electrode, and the second electrode thereof may be a drain electrode, but embodiments according to the present disclosure are not limited thereto.

Each of the driving transistor DT, the second transistor ST2, the fourth transistor ST4, the fifth transistor ST5, and the sixth transistor ST6 may include a silicon-based channel region. For example, each of the driving transistor DT, the second transistor ST2, the fourth transistor ST4, the fifth transistor ST5, and the sixth transistor ST6 may be formed of any one of polysilicon and amorphous silicon. When each of the driving transistor DT, the second transistor ST2, the fourth transistor ST4, the fifth transistor ST5, and the sixth transistor ST6 is formed of polysilicon, a process of forming the same may be a low temperature polycrystalline silicon (LTPS) process. The channel region formed of low-temperature polysilicon may have high electron mobility and excellent turn-on characteristics. Accordingly, because the display device 10 includes the driving transistor DT, the second transistor ST2, the fourth transistor ST4, the fifth transistor ST5, and the sixth transistor ST6 that have excellent turn-on characteristics, it may be possible to drive the plurality of pixels SP relatively stably and relatively efficiently.

Each of the driving transistor DT, the second transistor ST2, the fourth transistor ST4, the fifth transistor ST5, and the sixth transistor ST6 may correspond to a PMOS transistor. For example, each of the driving transistor DT, the second transistor ST2, the fourth transistor ST4, the fifth transistor ST5, and the sixth transistor ST6 may output a current flowing into the first electrode to the second electrode based on a gate low voltage applied to the gate electrode.

Each of the first transistor ST1 and the third transistor ST3 may include an oxide semiconductor-based channel region. For example, each of the first transistor ST1 and the third transistor ST3 may have a coplanar structure in which a gate electrode is located on the oxide semiconductor-based channel region. The transistor having the coplanar structure may have excellent off current characteristics and perform low frequency driving, thereby reducing power consumption. Accordingly, the display device 10 may include the first transistor ST1 and the third transistor ST3 having excellent off current characteristics, thereby preventing or reducing a leakage current from flowing in the pixel, and relatively stably maintaining the voltage in the pixel.

Each of the first transistor ST1 and the third transistor ST3 may correspond to an NMOS transistor. For example, each of the first transistor ST1 and the third transistor ST3 may output a current flowing into the first electrode to the second electrode based on a gate high voltage applied to the gate electrode.

The first capacitor Cst may be connected between the gate electrode of the driving transistor DT and the driving voltage line VDL. For example, the first capacitor electrode of the first capacitor Cst may be connected to the gate electrode of the driving transistor DT, and a second capacitor electrode of the first capacitor Cst may be connected to the driving voltage line VDL, so that a potential difference between the driving voltage line VDL and the gate electrode of the driving transistor DT may be maintained.

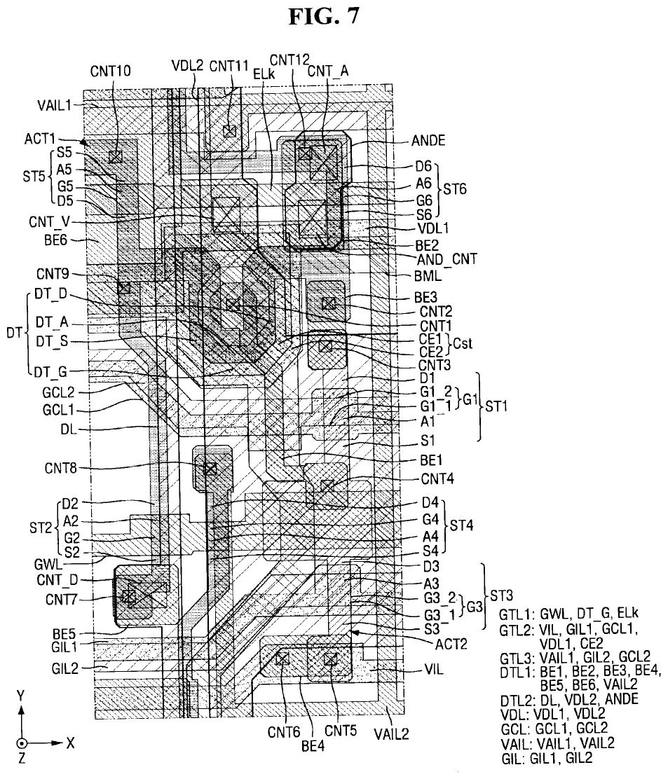

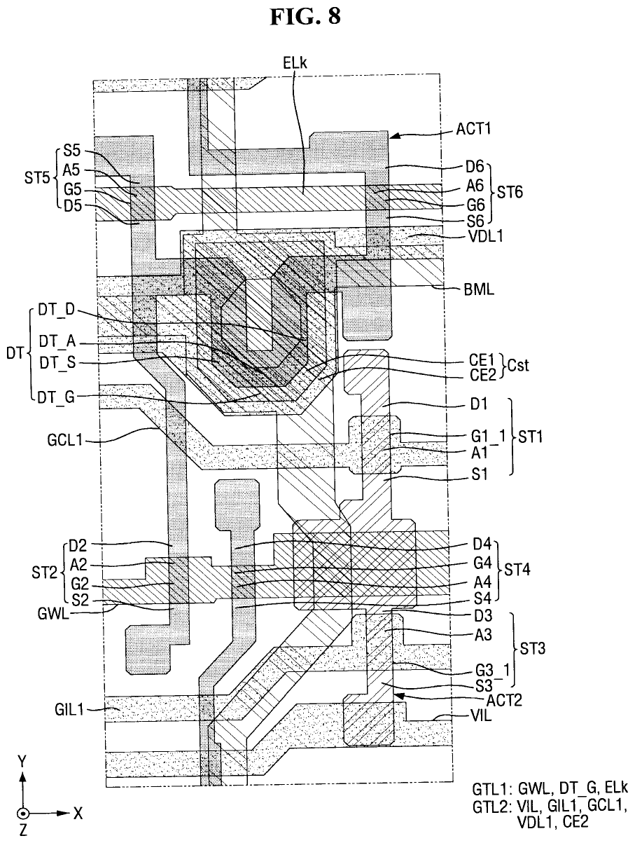

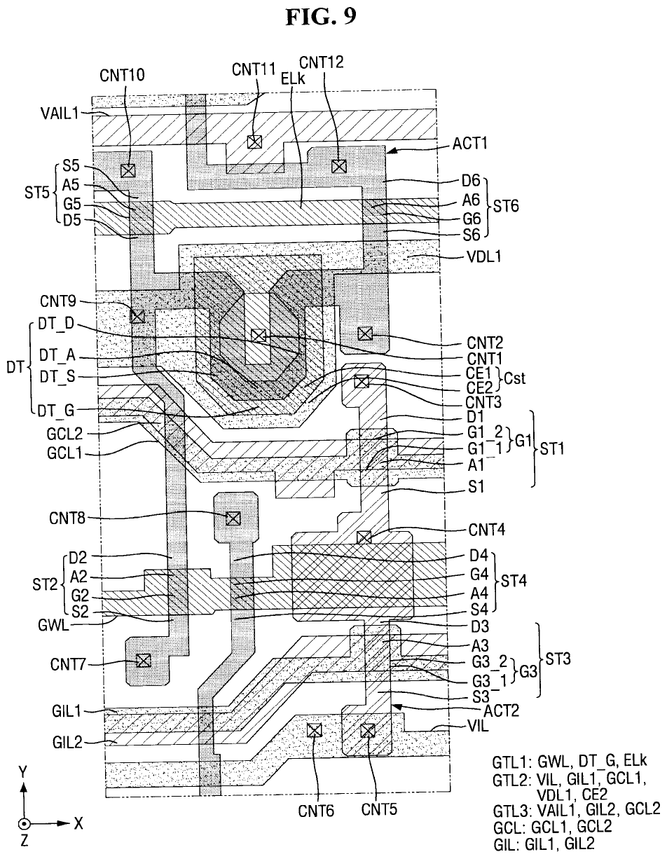

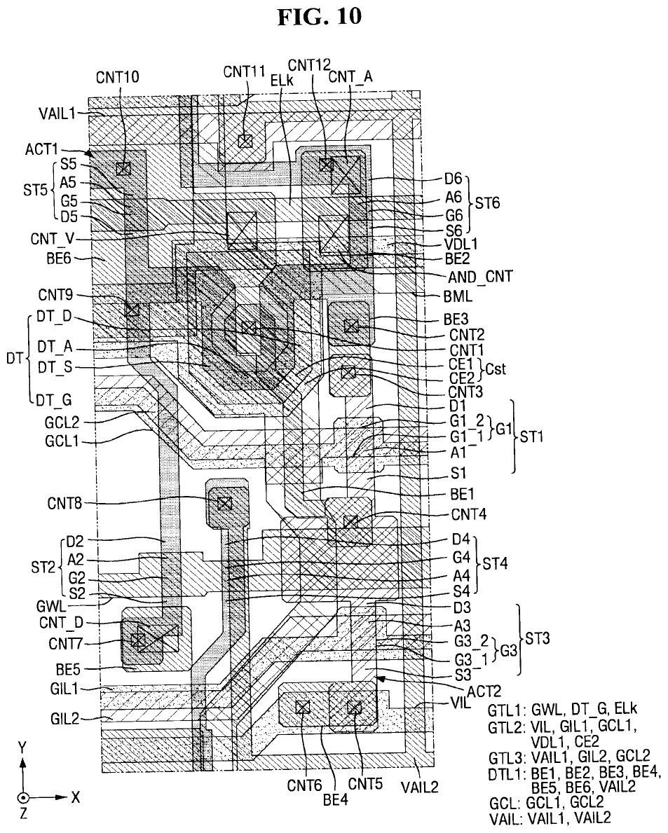

FIG. 7 is a plan view illustrating aspects of a pixel according to some embodiments. FIG. 8 is a plan view illustrating a lower metal layer, a first semiconductor layer, a first gate layer, a second gate layer, and a second semiconductor layer of FIG. 7. FIG. 9 is a plan view illustrating the first semiconductor layer, the first gate layer, the second gate layer, the second semiconductor layer, and a third gate layer of FIG. 7. FIG. 10 is a plan view illustrating a lower metal layer, a first semiconductor layer, a first gate layer, a second gate layer, a second semiconductor layer, a third gate layer, and a first data conductive layer that are sequentially stacked.

A lower metal layer BML may overlap the driving transistor DT in the thickness direction to block light incident toward the driving transistor DT. The lower metal layer BML blocks light incident toward the driving transistor DT, thereby relatively improving the turn-on characteristics of the transistor.

A first semiconductor layer ACT1 may include a driving channel DT_A, a first electrode DT_S, and a second electrode DT_D of the driving transistor DT, and channels A2, A4, A5, and A6, first electrodes S2, S4, S5, and S6, and second electrodes D2, D4, D5, and D6 of the second transistor ST2, the fourth transistor ST4, the fifth transistor ST5, and the sixth transistor ST6. For example, the first semiconductor layer ACT1 may be made of low-temperature polycrystalline silicon LTPS.

A first gate layer GTL1 may include the write scan line GWL, a gate electrode DT_G of the driving transistor DT, and the emission control line ELk. The write scan line GWL and the emission control line ELk may extend in the X-axis direction. The gate electrode DT_G of the driving transistor DT may be located between the write scan line GWL and the emission control line ELk.

A second gate layer GTL2 may include the second initialization voltage line VIL, a first sub-initialization scan line GIL1, a first sub-scan line GCL1, a first driving voltage line VDL1, and a second capacitor electrode CE2. The second initialization voltage line VIL, the first sub-initialization scan line GIL1, and the first sub-scan line GCL1 may extend in the X-axis direction.

A second semiconductor layer ACT2 may include the channels A1 and A3, the first electrodes D1 and D3, and the second electrodes S1 and S3 of the first transistor S1 and the third transistor ST3. For example, the second semiconductor layer ACT2 may be made of an oxide semiconductor.

A third gate layer GTL3 may include a first-first initialization voltage line VAIL1, a second sub-initialization scan line GTL2, and a second sub-scan line GCL2. The first-first initialization voltage line VAIL1, the second sub-initialization scan line GTL2, and the second sub-scan line GCL2 may extend in the X-axis direction. The second sub-initialization scan line GTL2 and the second sub-scan line GCL2 may overlap the first sub-initialization scan line GIL1 and the first sub-scan line GCL1, respectively.

A first data conductive layer DTL1 may include a first connection electrode BE1, a second connection electrode BE2, a third connection electrode BE3, a fourth connection electrode BE4, a fifth connection electrode BE5, a sixth connection electrode BE6, and a first-second initialization voltage line VAIL2. The first-second initialization voltage line VAIL2 may include a first portion extending in the X-axis direction and a second portion extending in the Y-axis direction. The first portion of the first-second initialization voltage line VAIL2 may overlap the first-first initialization voltage line VAIL1 in the Z-axis direction. That is, the first initialization voltage line VAIL may include the first-first initialization voltage line VAIL1 and the first-second initialization voltage line VAIL2. The first-first initialization voltage line VAIL1 and the first-second initialization voltage line VAIL2 may receive the same voltage. The first-first initialization voltage line VAIL1 and the first-second initialization voltage line VAIL2 may be connected to each other through an eleventh contact hole CNT11.

A second data conductive layer DTL2 may include the data line DL, a second driving voltage line VDL2, and an anode connection electrode ANDE. The data line DL and the second driving voltage line VDL2 may extend in the Y-axis direction.

Meanwhile, the initialization scan line GIL may include the first sub-initialization scan line GIL1 and the second sub-initialization scan line GIL2. The first sub-initialization scan line GIL1 and the second sub-initialization scan line GIL2 may include portions that overlap in the Z-axis direction, and may receive the same initialization scan signal. The first sub-initialization scan line GIL1 and the second sub-initialization scan line GIL2 may be connected to each other through a contact hole.

The scan control line GCL may include the first sub-scan line GCL1 and the second sub-scan line GCL2. The first sub-scan line GCL1 and the second sub-scan line GCL2 may include portions that overlap in the Z-axis direction, and may receive the same scan signal. The first sub-scan line GCL1 and the second sub-scan line GCL2 may be connected to each other through a contact hole.

Also, the driving voltage line VDL may include the first driving voltage line VDL1 and the second driving voltage line VDL2. The first driving voltage line VDL1 and the second driving voltage line VDL2 may include portions that overlap each other in the Z-axis direction. The first driving voltage line VDL1 and the second driving voltage line VDL2 may receive the same voltage. The first driving voltage line VDL1 and the second driving voltage line VDL2 may be connected to each other through a contact hole.

The driving transistor DT may include the driving channel DT_A, the gate electrode DT_G, the first electrode DT_S, and the second electrode DT_D. The driving channel DT_A of the driving transistor DT may be located in the first semiconductor layer ACT1 and may overlap the gate electrode DT_G of the driving transistor DT. For example, the first semiconductor layer ACT1 may be made of low-temperature polycrystalline silicon LTPS.

The gate electrode DT_G of the driving transistor DT may overlap the first connection electrode BE1. The gate electrode DT_G of the driving transistor DT may be connected to the first connection electrode BE1 through the first contact hole CNT1. The first connection electrode BE1 may be connected to the second electrode S1 of the first transistor ST1 through a fourth contact hole CNT4. Further, an area of the gate electrode DT_G of the driving transistor DT, which overlaps the second capacitor electrode CE2, may correspond to the first capacitor electrode CE1 of the first capacitor Cst.

The first electrode DT_S of the driving transistor DT may be connected to the second electrode D5 of the fifth transistor ST5 and the second electrode D2 of the second transistor ST2. The second electrode DT_D of the driving transistor DT may be connected to the first electrode S6 of the sixth transistor ST6, and connected to the third connection electrode BE3 through a second contact hole CNT2.

The first transistor ST1 may include the first channel A1, the gate electrode G1, the first electrode D1, and the second electrode S1. The first channel A1 of the first transistor ST1 may be located in the second semiconductor layer ACT2. The first channel A1 of the first transistor ST1 may overlap the gate electrode G1 of the first transistor ST1. The gate electrode G1 of the first transistor ST1 may include a lower gate electrode G1_1 and an upper gate electrode G1_2. The lower gate electrode G1_1 of the gate electrode G1 of the first transistor ST1 corresponds to a part of the first sub-scan line GCL1, and the upper gate electrode G1_2 thereof corresponds to a part of the second sub-scan line GCL2. The gate electrode G1 of the first transistor ST1 may be an overlapping area of the first channel A1 and the first and second sub-scan lines GCL1 and GCL2. The first transistor ST1 is formed in a double gate method in which a gate electrode is located at both the upper and lower portions of the semiconductor layer, thereby increasing carrier mobility in the first channel A1 and increasing a turn-on current by 20% or more.

The first electrode D1 of the first transistor ST1 may be connected to the third connection electrode BE3 through a third contact hole CNT3. The third connection electrode BE3 may be connected to the second electrode DT_D of the driving transistor DT through the second contact hole CNT2. The second electrode S1 of the first transistor ST1 may be connected to the first electrode D3 of the third transistor ST3, and may be connected to the first connection electrode BE1 through the fourth contact hole CNT4.

The second transistor ST2 may include the second channel A2, the gate electrode G2, the first electrode S2, and the second electrode D2. The second channel A2 of the second transistor ST2 may be located in the first semiconductor layer ACT1. The gate electrode G2 of the second transistor ST2 is a part of the write scan line GWL, and may be an overlapping area of the second channel A2 of the second transistor ST2 and the write scan line GWL.

The first electrode S2 of the second transistor ST2 may be connected to the fifth connection electrode 6E5 through a seventh contact hole CNT7. The fifth connection electrode 6E5 may be connected to the data line DL through a data contact hole CNT_D. The second electrode D2 of the second transistor ST2 may be connected to the first electrode DT_S of the driving transistor DT and the second electrode D5 of the fifth transistor ST5.

The third transistor ST3 may include the third channel A3, a gate electrode G3, the first electrode D3, and the second electrode S3. The third channel A3 of the third transistor ST3 may be located in the second semiconductor layer ACT2. The third channel A3 of the third transistor ST3 may overlap the gate electrode G3 of the third transistor ST3. The gate electrode G3 of the third transistor ST3 may include a lower gate electrode G3_1 and an upper gate electrode G3_2. The lower gate electrode G3_1 of the third transistor ST3 corresponds to a part of the first sub-initialization scan line GIL1, and the upper gate electrode G3_2 thereof corresponds to a part of the second sub-initialization scan line GIL2. The gate electrode G3 of the third transistor ST3 may be an overlapping area of the third channel A3 and the first and second sub-initialization scan lines GIL1 and GIL2. The third transistor ST3 is formed in a double gate method in which a gate electrode is located at both the upper and lower portions of the semiconductor layer, thereby increasing the carrier mobility in the first channel A3 and increasing a turn-on current by 20% or more.

The first electrode D3 of the third transistor ST3 may be connected to the second electrode S1 of the first transistor ST1, and the second electrode S3 of the third transistor ST3 may be connected to the fourth connection electrode BE4 through a fifth contact hole CNT5. The fourth connection electrode BE4 may be connected to the second initialization voltage line VIL through a sixth contact hole CNT6.

The fourth transistor ST4 may include the fourth channel A4, a gate electrode G4, the first electrode S4, and the second electrode D4. The fourth channel A4 of the fourth transistor ST4 may be located in the first semiconductor layer ACT1. The gate electrode G4 of the fourth transistor ST4 is a part of the write scan line GWL, and may be an overlapping area of the fourth channel A4 of the fourth transistor ST4 and the write scan line GWL.

The first electrode S4 of the fourth transistor ST4 may be connected to the second electrode D6 of the sixth transistor ST6 located in the previous pixel. The second electrode D4 of the fourth transistor ST4 may be connected to the first-second initialization voltage line VAIL2 through an eighth contact hole CNT8.

The fifth transistor ST5 may include the fifth channel A5, the gate electrode G5, the first electrode S5, and the second electrode D5. The fifth channel A5 of the fifth transistor ST5 may be located in the first semiconductor layer ACT1. The gate electrode G5 of the fifth transistor ST5 is a part of the emission control line ELk, and may be an overlapping area of the fifth channel A5 of the fifth transistor ST5 and the emission control line ELk.

The first electrode S5 of the fifth transistor ST5 may be connected to the sixth connection electrode BE6 through a tenth contact hole CNT10. The sixth connection electrode BE6 may be connected to the second driving voltage line VDL2 through a driving contact hole CNT_V. The second electrode D5 of the fifth transistor ST5 may be connected to the first electrode DT_S of the driving transistor DT and the second electrode D2 of the second transistor ST2.

The sixth transistor ST6 may include the sixth channel A6, the gate electrode G6, the first electrode S6, and the second electrode D6. The sixth channel A6 of the sixth transistor ST6 may be located in the first semiconductor layer ACT1. The gate electrode G6 of the sixth transistor ST6 is a part of the emission control line ELk, and may be an overlapping area of the sixth channel A6 of the sixth transistor ST6 and the emission control line ELk.

The first electrode S6 of the sixth transistor ST6 may be connected to the second electrode DT_D of the driving transistor DT. The second electrode D6 of the sixth transistor ST6 may be connected to the second connection electrode BE2 through a twelfth contact hole CNT12. The anode connection electrode ANDE may be connected to the second connection electrode BE2 through a first anode contact hole CNT_A. The pixel electrode may be connected to the anode connection electrode ANDE through a second anode contact hole AND_CNT.

The first capacitor Cst may include the first capacitor electrode CE1 and the second capacitor electrode CE2. The first capacitor electrode CE1 is a part of the gate electrode DT_G of the driving transistor DT, which corresponds to an area of the gate electrodes DT_G of the driving transistor DT that overlaps the first capacitor electrode CE1 of the first capacitor Cst. The second capacitor electrode CE2 may be connected to the sixth connection electrode BE6 through a ninth contact hole CNT9. The sixth connection electrode BE6 may be connected to the second driving voltage line VDL2 through the driving contact hole CNT_V.

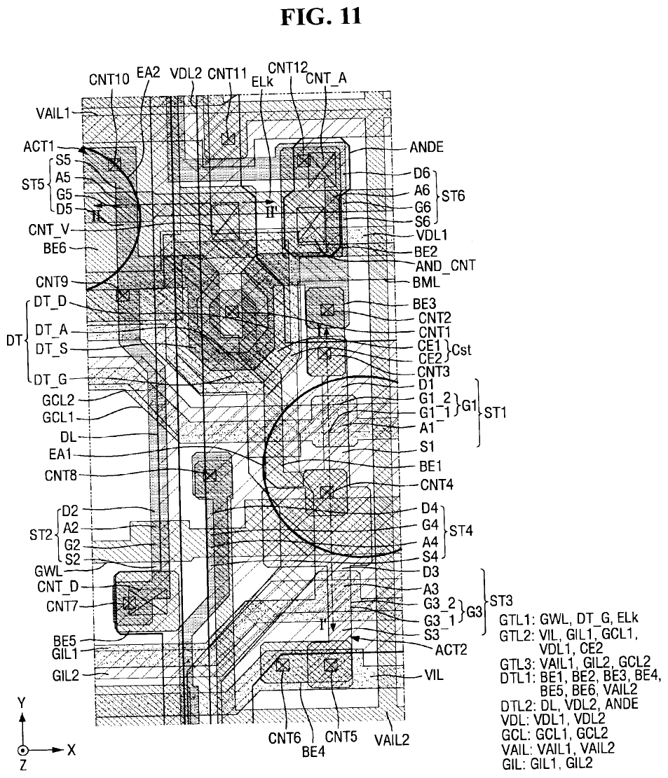

FIG. 11 is a diagram illustrating a lower metal layer, the first semiconductor layer ACT1, the first gate layer GTL1, the second gate layer GTL2, the second semiconductor layer ACT2, the third gate layer GTL3, the first data conductive layer DTL1, the second data conductive layer DTL2, and light emitting element that are sequentially stacked.

In FIG. 11, the above description is omitted, and the arrangement relationship of the emission areas EA1 and EA2, the first data conductive layer DTL1, and the second data conductive layer DTL2 will be mainly described.

Referring to FIG. 11, the data line DL included in the second data conductive layer DTL2 may be arranged to extend in the Y-axis direction, and may overlap, in the Z-axis direction, the write scan line GWL and the emission control line ELk included in the first gate layer GTL1, the second initialization voltage line VIL, the first sub-initialization scan line GIL1, the first sub-scan line GCL1, and the first driving voltage line VDL1 included in the second gate layer GTL2, and the first-first initialization voltage line VAIL1, the second sub-initialization scan line GTL2, and the second sub-scan line GCL2 included in the third gate layer GTL3 that extend in the X-axis direction.

Also, the data line DL may overlap a part of the fifth connection electrode BE5 and a part of the sixth connection electrode BE6 in the Z-axis direction, and may not overlap the second emission area EA2 arranged on the sixth connection electrode BE6. That is, the data line DL may extend in the Y-axis direction while bypassing the second emission area EA2 arranged on the sixth connection electrode BE6.

Similarly to the data line DL, the second driving voltage line VDL2 may be arranged to extend in the Y-axis direction, and may overlap, in the Z-axis direction, the write scan line GWL and the emission control line ELk included in the first gate layer GTL1, the second initialization voltage line VIL, the first sub-initialization scan line GIL1, the first sub-scan line GCL1, and the driving voltage line VDL1 included in the second gate layer GTL2, and the first-first initialization voltage line VAIL1, the second sub-initialization scan line GTL2, and the second sub-scan line GCL2 included in the third gate layer GTL3 that extend in the X-axis direction.

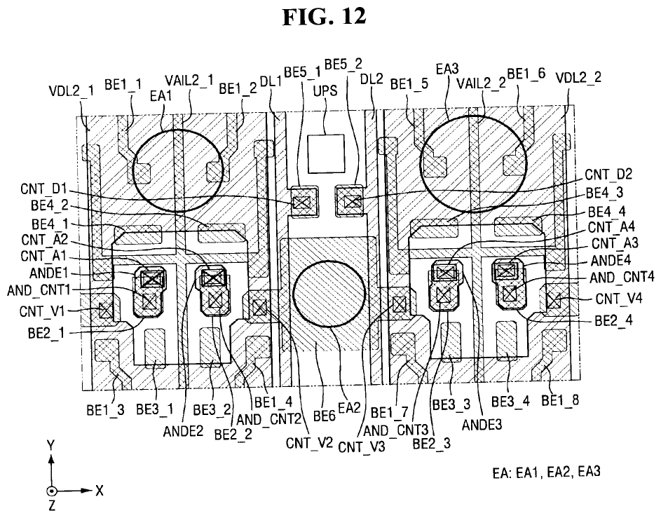

FIG. 12 is a plan view illustrating a first data conductive layer, a second data conductive layer, and an emission area of a plurality of pixels according to some embodiments.

In FIG. 12, a lower metal layer, a first semiconductor layer, a first gate layer, a second gate layer, a second semiconductor layer, and a third gate layer are not illustrated to describe the arrangement relationship of the emission area, the first data conductive layer, and the second data conductive layer.

Further, in FIG. 12, electrodes and contact holes located in the peripheral region of the first emission area EA1 and the second emission area EA2 will be mainly described. Because the descriptions of the electrodes and the contact holes located in the peripheral region of the first emission area EA1 and the second emission area EA2 may be applied substantially equally to electrodes and contact holes located in the peripheral region of the third emission area EA3, the description thereof will be omitted.

Referring to FIG. 12, the plurality of pixels SP may include the first emission area EA1, the second emission area EA2, and the third emission area EA3. For example, as described above, the first emission area EA1 may emit red light, and the second emission area EA2 may emit green light, but embodiments according to the present disclosure are not limited thereto. Also, according to some embodiments, the size of the first emission area EA1 may be greater than the size of the second emission area EA2, but embodiments according to the present disclosure are not limited thereto. In some embodiments, the sizes of the first to third emission areas EA1, EA2, and EA3 may be the same.

Referring to FIG. 12, according to some embodiments, the first emission area EA1 may be located on a second-first driving voltage line VDL2_1, the second emission area EA2 may be located on the sixth connection electrode BE6, and the third emission area may be located in a second-second driving voltage line VDL2_2. For example, the first emission area EA1 and the third emission area EA3 may be respectively located in the second-first driving voltage line VDL2_1 and the second-second driving voltage line VDL2_2 to form a first row, and may be alternately arranged in the X-axis direction. The second emission areas EA2 may form a second row and may be arranged in the X-axis direction. That is, each of the second emission areas EA2 forming the second row may be arranged to be shifted from the first emission area EA1 and the third emission area EA3 forming the first row. However, embodiments according to the present disclosure are not limited thereto, and the arrangement of the emission areas EA included in the plurality of pixels SP may vary in some embodiments.

In the peripheral region of the first emission area EA1 and the second emission area EA2 shown in FIG. 12, a plurality of first connection electrodes BE1_1, BE1_2, BE1_3, BE1_4, a plurality of second connection electrodes BE2_1 and BE2_2, a plurality of third connection electrodes BE3_1 and BE3_2, a plurality of fourth connection electrodes BE4_1 and BE4_2, a plurality of fifth connection electrodes BE5_1 and BE5_2, the sixth connection electrode BE6 and a first-second-a initialization voltage line VAIL2_1 may be located.

The first-second-a initialization voltage line VAIL2_1 may include a first portion that overlaps the central portion of the first emission area EA1, a second portion that does not overlap the first emission area EA1 and extends from the first portion of the first-second-a initialization voltage line VAIL2_1 in the X-axis direction, and a third portion that does not overlap the first emission area EA1 and extends from the second portion in the arrangement direction of the first emission area EA1. That is, the first portion of the first-second-a initialization voltage line VAIL2_1 may be arranged to overlap the plurality of pixels SP, which are located adjacent to each other in the Y-axis direction, in the Z-axis direction. The second portion may be symmetrically located in the pixels SP that are adjacent to each other in the X-axis direction. The third portion may have a length smaller than the first portion in the Y-axis direction and may be symmetrically arranged in the pixels SP that are adjacent to each other in the X-axis direction.

The first-first connection electrode BE1_1 and the first-second connection electrode BE1_2, which are included in the respective pixels SP adjacent to each other in the X-axis direction, may be symmetrically arranged in the X-axis direction with respect to a Y-axis. The first-third connection electrodes BE1_3 and the first-fourth connection electrodes BE1_4, which are included in the respective pixels adjacent to each other in the X-axis direction, may be symmetrically arranged in the X-axis direction with respect to the Y-axis.

The second connection electrodes BE2_1 and BE2_2 and the third connection electrodes BE3_1 and BE3_2 may be located in an opening included in the second-first driving voltage line VDL2_1. The second-first connection electrode BE2_1 and the second-second connection electrode BE2_2 may be symmetrically arranged in the X-axis direction with respect to the first portion of the first-second-a initialization voltage line VAIL2_1. The third-first connection electrode BE3_1 and the third-second connection electrode BE3_2 may be symmetrically arranged in the X-axis direction with respect to the first portion of the first-second-a initialization voltage line VAIL2_1. However, the third connection electrodes BE3_1 and BE3_2 may include portions that partially overlap the second-first driving voltage line VDL2_1 in the Z-axis direction.

Also, the fourth connection electrodes BE4_1 and BE4_2 may partially overlap the opening of the second-first driving voltage line VDL2_1 in the Z-axis direction, and may be symmetrically arranged in the X-axis direction with respect to the first portion of the first-second-a initialization voltage line VAIL2_1.

The fifth connection electrodes BE5_1 and BE5_2 are symmetrically located in the pixels SP that are located adjacent to each other in the X-axis direction, and may overlap the data lines DL1 and DL2 in the Z-axis direction.

Anode connection electrodes ANDE1 and ANDE2 may overlap the second connection electrodes BE2_1 and BE2_2, which are located in the opening of the second-first driving voltage line VDL2_1, in the Z-axis direction, and may be symmetrically arranged in the X-axis direction with respect to the first portion of the first-second-a initialization voltage line VAIL2_1.

The sixth connection electrode BE6 may have a greater size than the second emission area EA2 in a plan view and may overlap the second emission area EA2 in the Z-axis direction. For example, the sixth connection electrode BE6 may include a first portion that overlaps the second emission area EA2 in the Z-axis direction and a second portion that protrudes from the first portion and does not overlap the second emission area EA2 in the Z-axis direction. The first portion may not include an opening penetrating in the Z-axis direction, and may have a rectangular shape that extends in the X-axis direction and the Y-axis direction to have a flat surface. That is, the first portion may have a plate shape.

The second portion may be smaller than the first portion and may have a rectangular shape with rounded corners. The first portion and the second portion may be integrally formed. Because the second emission area EA2 has a smaller size than the first portion of the sixth connection electrode BE6, it may be included in the first portion of the sixth connection electrode BE6 in a plan view. That is, the second emission area EA2 may completely overlap the sixth connection electrode BE6 in a plan view. In other words, the second emission area EA2 may overlap the sixth connection electrode BE6 within all edges thereof in a plan view. Accordingly, the sixth connection electrode BE6 may serve as a connection electrode, and may be located under the second emission area EA2 to planarize the lower portion of the second emission area EA2.

The data lines DL1 and DL2 may be arranged to be spaced apart from each other in the X-axis direction with the second emission area EA2 interposed therebetween. Each of the first and second data lines DL1 and DL2 may extend in the Y-axis direction. That is, because the first data line DL1 and the second data line DL2 overlap the sixth connection electrode BE6 in the Z-axis direction, and extend in the Y-axis direction while bypassing the second emission area EA2, they may not overlap the second emission area EA2 in the Z-axis direction.

For example, each of the first data line DL1 and the second data line DL2 may include a first portion that overlaps the sixth connection electrode BE6 and does not overlap the second emission area EA2, and a second portion that does not overlap the sixth connection electrode BE6.

The second-first driving voltage line VDL2_1 may be arranged to extend in the Y-axis direction and may overlap the first emission area EA1 located on the second-first driving voltage line VDL2_1 in the Z-axis direction.

For example, the second-first driving voltage line VDL2_1 may include a portion that overlaps the first emission area EA1 in the Z-axis direction. That is, the portion overlapping the first emission area EA1 may not include an opening that penetrates in the Z-axis direction, and may have a rectangular shape that extends in the X-axis direction and the Y-axis direction to have a flat surface. Accordingly, the portion overlapping the first emission area EA1 may have a plate shape. Because the first emission area EA1 has a smaller size than the second-first driving voltage line VDL2_1, it may completely overlap the second-first driving voltage line VDL2_1 in a plan view, and may be included in a first portion of the second-first driving voltage line VDL2_1. Accordingly, the second-first driving voltage line VDL2_1 may serve to apply a voltage for driving the light emitting element and may be located under the first emission area EA1 to planarize the lower portion of the first emission area EA1.

The sensing device UPS may be located between the first data line DL1 and the second data line DL2. For example, the second portion of the first data line DL1 and the second portion of the second data line DL2 may be arranged in parallel with each other while being spaced apart from each other in the X-axis direction with the sensing device UPS interposed therebetween. Also, the sensing device UPS may be located between the first emission area EA1 and the third emission area EA3. That is, the first emission area EA1 and the third emission area EA3 may be arranged to be spaced apart from each other in the X-axis direction with the sensing device UPS interposed therebetween. In addition, the sensing device UPS may not overlap the first data conductive layer DTL1 the second data conductive layer DTL2, and the first to third emission areas EA1, EA2, and EA3 in the Z-axis direction.

The above descriptions are equally applied to driving contact holes CNT_V1, CNT_V2, CNT_V3 and CNT_V4, data contact holes CNT_D1 and CNT_D2, first anode contact holes CNT_A1, CNT_A2, CNT_A3, and CNT_A4, and second anode contact holes AND_CNT1, AND_CNT2, AND_CNT3, and AND_CNT4 shown in FIG. 12, and thus descriptions thereof will be omitted.

In addition, the descriptions of the connection electrodes and the contact holes located in the first emission area EA1 and the second emission area EA2 may be applied substantially equally to first connection electrodes BE1_5, BE1_6, BE1_7, and BE1_8, second connection electrodes BE2_3 and BE2_4, third connection electrodes BE3_3 and BE3_4, fourth connection electrodes BE4_3 and BE4_4, and anode connection electrodes ANDE3 and ANDE4 that are located a region where the third emission area EA3 is located.

Hereinafter, other embodiments of the display device will be described in more detail. In the following embodiments, description of the same components as those of the above-described embodiments, which are denoted by like reference numerals, will be omitted or simplified, and differences will be mainly described.

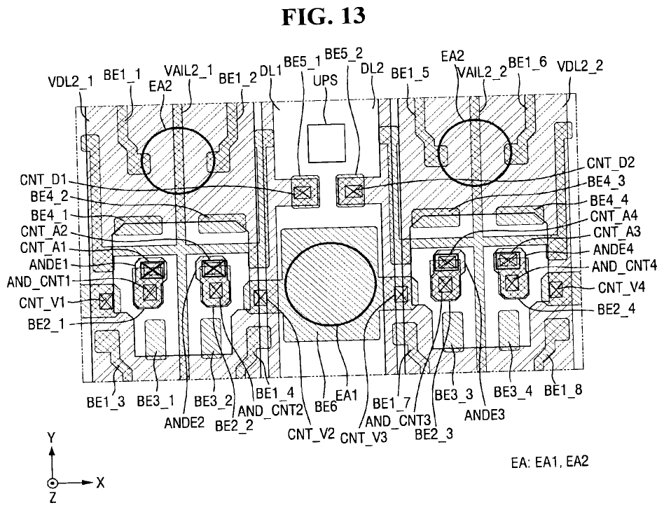

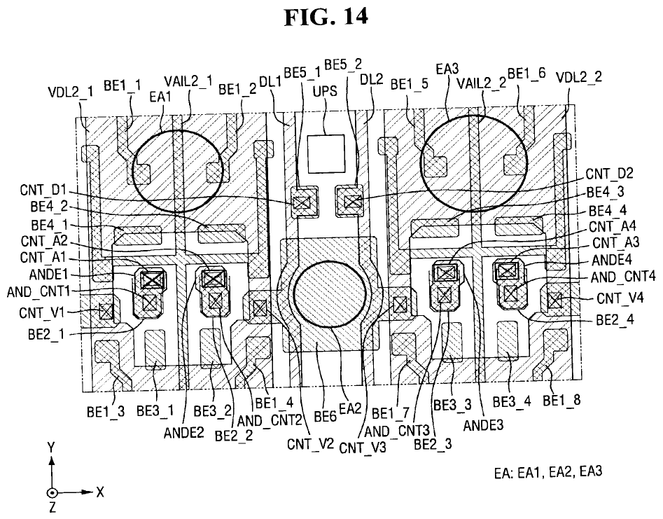

FIG. 13 is a plan view illustrating a first data conductive layer, a second data conductive layer, and an emission area of a plurality of pixels according to some embodiments. FIG. 14 is a plan view illustrating a first data conductive layer, a second data conductive layer, and an emission area of a plurality of pixels according to some embodiments.

The embodiments illustrated with respect to FIG. 13 are different from the embodiments illustrated with respect to FIG. 12 in that the first emission area EA1 may be located on the sixth connection electrode BE6, and the second emission areas EA2 may be located on the second-first driving voltage line VDL2_1 and the second-second driving voltage line VDL2_2. According to some embodiments, the third emission area EA3 may be located on the sixth connection electrode BE6 included in the pixel SP that is adjacent to the sixth connection electrode BE6 in the X-axis direction.

For example, the second emission areas EA2 may be arranged in the X-axis direction to form a first row. The first emission area EA1 and the third emission area EA3 may be located on the sixth connection electrodes BE6 included in the respective pixels SP that are adjacent to each other in the X-axis direction to form a second row, and may be alternately arranged in the X-axis direction. That is, each of the first emission area EA1 and the third emission area EA3 forming the second row may be arranged to be shifted from the second emission areas EA2 forming the first row.

The embodiments illustrated with respect to FIG. 14 are different from the embodiments illustrated with respect to FIG. 12 in that the data lines DL1, which extend in the Y-axis direction while interposing the second emission area EA2 located on the sixth connection electrode BE6 therebetween, partially include a curve.

For example, a first portion of the first data line DL1 may have a curved shape. The first portion may bypass the second emission area EA2 along the surface shape of the second emission area EA2 without overlapping the second emission area EA2. Further, unlike the first portion, the second portion of the first data line DL1 may have a linear shape without overlapping the sixth connection electrode BE6 and the second emission area EA2. The description of the first data line DL1 may be equally applied to the second data line DL2. That is, a first portion of the second data line DL2, which faces the first portion of the first data line DL1 while being spaced apart therefrom with the second emission area EA2 interposed therebetween, may also have a curved shape. Like the first portion of the first data line DL1, the first portion of the second data line DL2 may bypass the second emission area EA2 along the surface shape of the second emission area EA2 and may not overlap the second emission area EA2. However, embodiments according to the present disclosure are not limited thereto. In some embodiments, the first portion of the data lines DL1 and DL2 may have various shapes according to the planar shape of the second emission area EA2. For example, when the second emission area EA2 has a polygonal shape in a plan view, the first portion of the data lines DL1 and DL2 may have the same shape as the shape of the second emission area EA2. According to some embodiments, at least one of the first portion of the first data line DL1 or the first portion of the second data line DL2 may have a curved shape.

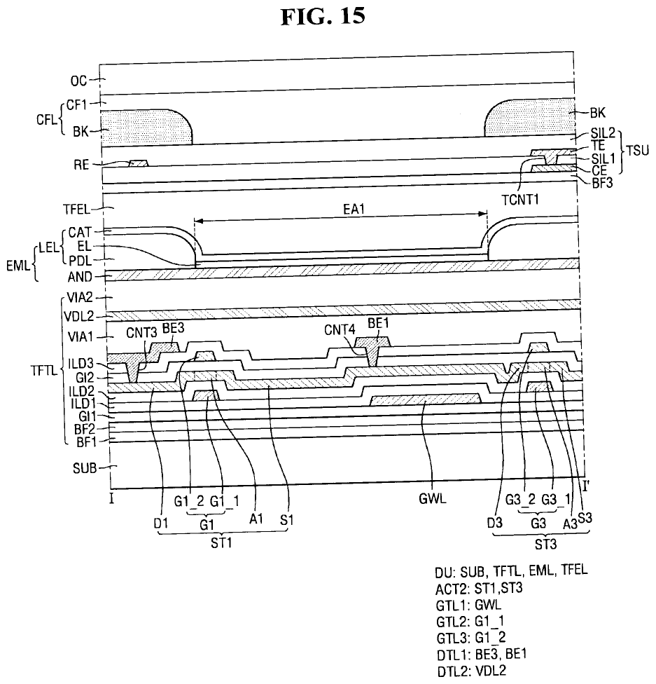

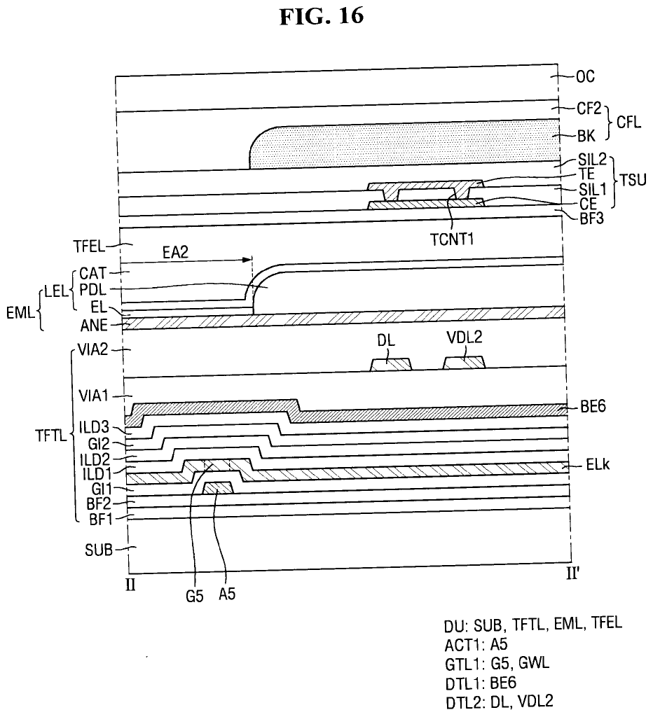

FIG. 15 is a cross-sectional view illustrating an example taken along the line I-I′ of FIG. 11. FIG. 16 is a cross-sectional view illustrating an example taken along the line II-II′ of FIG. 11.

Referring to FIGS. 15 and 16, the display panel 100 may include a display unit DU, a touch sensing unit TSU, and a color filter layer CFL. The display unit DU may include the substrate SUB, the thin film transistor layer TFTL, the light emitting element layer EML, and the encapsulation layer TFEL.

The substrate SUB may be a base substrate, and may be made of an insulating material such as polymer resin. For example, the substrate SUB may be a flexible substrate which can be bent, folded and rolled. The substrate SUB may include a polymer resin such as polyimide (PI), but embodiments according to the present disclosure are not limited thereto. In some embodiments, the substrate SUB may include a glass material or a metal material.

The thin film transistor layer TFTL may include a first buffer layer BF1, a second buffer layer BF2, the first semiconductor layer ACT1, a first gate insulating layer GI1, the first gate layer GTL1, a first interlayer insulating layer ILD1, the second gate layer GTL2, a second interlayer insulating layer ILD2, the second semiconductor layer ACT2, a second gate insulating layer GI2, the third gate layer GTL3, a third interlayer insulating layer ILD3, the first data conductive layer DTL1, a first via insulating layer VIA1, the second data conductive layer DTL2, and a second via insulating layer VIA2.

The first buffer layer BF1 may be formed on one surface of the substrate SUB. The buffer layer BF may be formed on one surface of the substrate SUB to protect the thin film transistors and the light emitting layer EL of the light emitting element layer EML from moisture permeating through the substrate SUB susceptible to moisture permeation.

According to some embodiments, the lower metal layer BML may be located on the first buffer layer BF1. For example, the lower metal layer BML may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof. According to some embodiments, the lower metal layer BML may be an organic layer including a black pigment.

The second buffer layer BF2 may be located on the first buffer layer BF1. The second buffer layer BF2 may include an inorganic layer capable of preventing or reducing penetration of air, moisture, or other contaminants. For example, the second buffer layer BF2 may include a plurality of inorganic layers alternately stacked.

The first semiconductor layer ACT1 may be located on the second buffer layer BF2. The first semiconductor layer ACT1 may be made of a silicon-based material. For example, the first semiconductor layer ACT1 may be made of low-temperature polycrystalline silicon LTPS.

The first gate insulating layer GI1 may cover the second buffer layer BF2 and the first semiconductor layer ACT1, and may insulate the first semiconductor layer ACT1 from the first gate layer GTL1.

The first gate layer GTL1 may be located on the first gate insulating layer GI1. The first gate layer GTL1 may include the write scan line GWL and the emission control lines ELk as well as the gate electrodes DT_G, G2, G4, G5, and G6 of the driving transistor DT, the second transistor ST2, the fourth transistor ST4, the fifth transistor ST5, and the sixth transistor ST6. The first gate layer GTL1 may be formed as a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

The first interlayer insulating layer ILD1 may cover the first gate layer GTL1 and the first gate insulating layer GI1. The first interlayer insulating layer ILD1 may insulate the first gate layer GTL1 from the second gate layer GTL2.

The second gate layer GTL2 may be located on the first interlayer insulating layer ILD1. The second gate layer GTL2 may include the second initialization voltage line VIL, the first sub-initialization scan line GIL1, the first sub-scan line GCL1, the first driving voltage line VDL1, and the second capacitor electrode CE2. The second gate layer GTL2 may include a lower gate electrode G1-1 of the first transistor ST1 and a lower gate electrode G3-1 of the third transistor ST3. The second gate layer GTL2 may include the same material as the above-described first gate layer GTL1.

The second interlayer insulating layer ILD2 may cover the second gate layer GTL2 and the first interlayer insulating layer ILD1. The second interlayer insulating layer ILD2 may insulate the second gate layer GTL2 from the second semiconductor layer ACT2.

The second semiconductor layer ACT2 may be located on the second interlayer insulating layer ILD2. For example, the second semiconductor layer ACT2 may be formed of an oxide-based material.

The second gate insulating layer GI2 may cover the second interlayer insulating layer ILD2 and the second semiconductor layer ACT2, and may insulate the second semiconductor layer ACT2 from the third gate layer GTL3.

The third gate layer GTL3 may be located on the second gate insulating layer GI2. The third gate layer GTL3 may include the first-first initialization voltage line VAIL1, the second sub-initialization scan line GTL2, and the second sub-scan line GCL2. The third gate layer GTL3 may include an upper gate electrode G1-2 of the first transistor ST1 and the upper gate electrode G1-2 of the third transistor ST3. The third gate layer GTL3 may include the same material as the above-described first gate layer GTL1.

The third interlayer insulating layer ILD3 may cover the third gate layer GTL3 and the second gate insulating layer GTL2. The third interlayer insulating layer ILD3 may insulate the third gate layer GTL3 from the first data conductive layer DTL1.

The first data conductive layer DTL1 may be located on the third interlayer insulating layer ILD3. The first data conductive layer DTL1 may include the first connection electrode BE1, the second connection electrode BE2, the third connection electrode BE3, the fourth connection electrode BE4, the fifth connection electrode BE5, the sixth connection electrode BE6, and the first-second initialization voltage line VAIL2. The first data conductive layer DTL1 may be formed of a single layer or multiple layers including any one of molybdenum (Mo), aluminum (Al), chromium (Cr), gold (Au), titanium (Ti), nickel (Ni), neodymium (Nd), and copper (Cu), or an alloy thereof.

The first via insulating layer VIA1 may cover the first data conductive layer DTL1 and the third interlayer insulating layer ILD3. The first via insulating layer VIA1 may flatten steps caused by the first semiconductor layer ACT1, the first gate layer GTL1, the second gate layer GTL2, the third gate layer GTL3, and the first data conductive layer DTL1. The first via insulating layer VIA1 may be formed of an organic layer such as an acryl resin, an epoxy resin, a phenolic resin, a polyamide resin, a polyimide resin, or the like.

The second data conductive layer DTL2 may be located on the first via insulating layer VIA1. The second data conductive layer DTL2 may include the data line DL, the second driving voltage line VDL2, and the anode connection electrode ANDE. The second data conductive layer DTL2 may include the same material as the above-described first data conductive layer DTL1.

The second via insulating layer VIA2 may cover the first data conductive layer DTL1 and the first via insulating layer VIA1. The second via insulating layer VIA2 may flatten a step caused by the first data conductive layer DTL1. The second via insulating layer VIA2 may include the same material as the first via insulating layer VIA1 described above.

The third contact hole CNT3 may be a hole that penetrates the second gate insulating layer GI2 and the third interlayer insulating layer ILD3 to expose the first electrode D1 of the first transistor ST1. The third connection electrode BE3 may be connected to the first electrode D1 of the first transistor ST1 through the third contact hole CNT3.

The fourth contact hole CNT4 may be a hole that penetrates the second gate insulating layer GI2 and the third interlayer insulating layer ILD3 to expose the second electrode S1 of the first transistor ST1. The first connection electrode BE1 may be connected to the second electrode S1 of the first transistor ST1 through the fourth contact hole CNT4.

The light emitting element layer EML may be located on the thin film transistor layer TFTL. The light emitting element layer EML may include the light emitting element LEL and a pixel defining layer PDL. The light emitting element LEL may include a pixel electrode AND, a light emitting layer EL, and a common electrode CAT.

The pixel electrode AND may be arranged to overlap one of the first to third emission areas EA1, EA2, and EA3 defined by the opening of the pixel defining layer PDL. The pixel electrode AND may have a single-layer structure of molybdenum (Mo), titanium (Ti), copper (Cu) or aluminum (Al), or may have a stacked-layer structure, for example, multiple layers of ITO/Mg, ITO/MgF, ITO/Ag, and ITO/Ag/ITO including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), or nickel (Ni), but embodiments according to the present disclosure are not limited thereto.

The light emitting layer EL may be located on the pixel electrode AND. For example, the light emitting layer EL may be an organic light emitting layer made of an organic material, but embodiments according to the present disclosure are not limited thereto. For example, when the light emitting layer EL corresponds to the organic light emitting layer, the emission area EA of each pixel represents an area in which the pixel electrode AND, the light emitting layer EL, and a common electrode CAT are sequentially stacked, and holes from the pixel electrode AND and electrons from the common electrode CAT are combined with each other in the light emitting layer EL to emit light.

The common electrode CAT may be arranged on the light emitting layer EL. For example, the common electrode CAT may be made in the form of an electrode common to all of the pixels rather than specific to each of the pixels. The common electrode CAT may be located on the light emitting layer EL in the first to third emission areas EA1, EA2, and EA3, and may be located on the pixel defining layer PDL in an area other than the first to third emission areas EA1, EA2, and EA3. The common electrode CAT may include a conductive material having a low work function, for example, Li, Ca, LiF/Ca, LiF/Al, A1, Mg, Ag, Pt, Pd, Ni, Au Nd, Ir, Cr, BaF, Ba, or a compound or mixture thereof (e.g., a mixture of Ag and Mg, etc.). Alternatively, the common electrode 173 may include a transparent metal oxide, for example, indium-tin-oxide (ITO), indium-zinc-oxide (IZO), zinc oxide (ZnO) or the like.

The pixel defining layer PDL may define the first to third emission areas EA1, EA2, and EA3 by the openings. The pixel defining layer PDL may separate and insulate the pixel electrodes AND of the respective light emitting elements LEL from each other. The pixel defining layer PDL may include a light absorbing material. The pixel defining layer PDL may prevent or reduce light reflection. The pixel defining layer PDL may be formed of an organic layer such as acryl resin, epoxy resin, phenolic resin, polyamide resin, polyimide resin and the like.

The second driving voltage line VDL2 may overlap the first emission area EA1 and the pixel defining layer PDL. Further, the sixth connection electrode BE6 may overlap the second emission area EA2 and the pixel defining layer PDL. The data line DL and the second driving voltage line VDL2 may not overlap the second emission area EA2 but may overlap the pixel defining layer PDL.

The encapsulation layer TFEL may be located on the light emitting element layer EML. The encapsulation layer TFEL may include at least one inorganic layer to prevent or reduce instances of oxygen, moisture, or other contaminants permeating into the light emitting layer EL. In addition, the encapsulation layer TFEL may include at least one organic layer to protect the light emitting layer EL from foreign substances such as dust. For example, the encapsulation layer TFEL may be formed in a structure in which a first inorganic layer, an organic layer, and a second inorganic layer are sequentially stacked. The first inorganic layer and the second inorganic layer may be formed as a multilayer in which one or more inorganic layers selected from a silicon nitride layer, a silicon oxynitride layer, a silicon oxide layer, a titanium oxide layer, and an aluminum oxide layer are alternately stacked. The organic layer may be an organic layer such as acrylic resin, epoxy resin, phenolic resin, polyamide resin, or polyimide resin.

The touch sensing unit TSU may be located on the encapsulation layer TFEL. The touch sensing unit TSU may include a third buffer layer BF3, the bridge electrode CE, a first insulating layer SIL1, the driving electrode TE, the sensing electrode RE, and a second insulating layer SIL2.

The third buffer layer BF3 may be located on the encapsulation layer TFEL. The third buffer layer BF3 may have an insulating and optical function. The third buffer layer BF3 may include at least one inorganic layer. Optionally, the third buffer layer BF3 may be omitted.

The bridge electrode CE may be located on the third buffer layer BF3. The bridge electrode CE may be located on a different layer from the driving electrode TE and the sensing electrode RE to electrically connect the driving electrodes TE adjacent in the Y-axis direction to each other.

The first insulating layer SIL1 may cover the bridge electrode CE and the third buffer layer BF3. The first insulating layer SIL1 may have an insulating and optical function. For example, the first insulating layer SIL1 may be an inorganic layer containing at least one of a silicon nitride layer, a silicon oxynitride layer, a silicon oxide layer, a titanium oxide layer, or an aluminum oxide layer.

The driving electrode TE and the sensing electrode RE may be located on the first insulating layer SIL1. Each of the driving electrode TE and the sensing electrode RE may not overlap the first to third emission areas EA1, EA2, and EA3. Each of the driving electrode TE and the sensing electrode RE may be formed of a single layer containing molybdenum (Mo), titanium (Ti), copper (Cu), aluminum (Al), or indium tin oxide (ITO), or may be formed to have a stacked structure (Ti/A1/Ti) of aluminum and titanium, a stacked structure (ITO/Al/ITO) of aluminum and ITO, an Ag—Pd—Cu (APC) alloy, or a stacked structure (ITO/APC/ITO) of APC alloy and ITO.

The second insulating layer SIL2 may cover the driving electrode TE, the sensing electrode RE, and the first insulating layer SIL1. The second insulating layer SIL2 may have an insulating and optical function. The second insulating layer SIL2 may be made of the material described in association with the first insulating layer SIL1.

The color filter layer CFL may be located on the touch sensing unit TSU. The color filter layer CFL may include a light blocking member BK, a first color filter CF1, a second color filter CF2, and a planarization layer OC.

The light blocking member BK may be located on the second insulating layer SIL2. The light blocking member BK may include a light absorbing material. For example, the light blocking member BK may include an inorganic black pigment or an organic black pigment. The inorganic black pigment may be carbon black, and the organic black pigment may include at least one of lactam black, perylene black, or aniline black, but embodiments according to the present disclosure are not limited thereto. The light blocking member BK may prevent or reduce visible light infiltration and color mixture between the first to third emission areas EA1, EA2, and EA3, which may lead to the relative improvement of color reproducibility of the display device 10. The first color filter CF1 may be arranged to correspond to the first emission area EA1, and the second color filter CF2 may be arranged to correspond to the second emission area EA2. The first and second color filters CF1 and CF2 may be located on the second insulating layer SIL2 in the first and second emission areas EA1 and EA2, and may be located on the light blocking member BK in a light blocking area. The first and second color filters CF1 and CF2 may absorb a part of the light coming from the outside of the display device 10 to reduce the reflected light of the external light. Thus, the first and second color filters CF1 and CF2 may prevent or reduce color distortion caused by the reflection of external light.

The planarization layer OC may be located on the first and second color filters CF1 and CF2 to planarize the upper end of the color filter layer CFL. For example, the planarization layer OC may include an organic material.

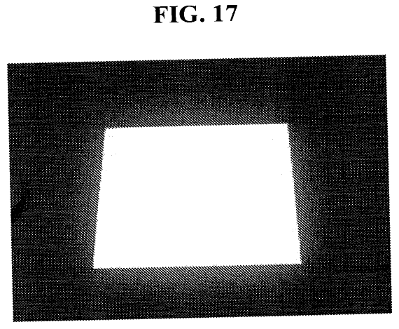

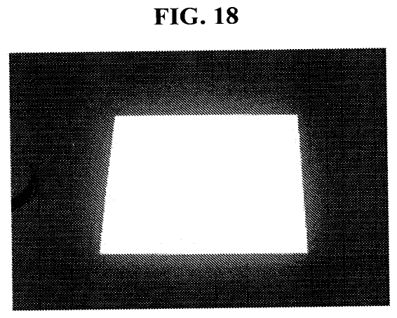

FIG. 17 is an image of a display device in which a reflective color band is generated when a second data conductive layer is located under an emission area. FIG. 18 is an image of a display device in which a reflective color band is generated when a second data conductive layer is not located under an emission area.

Referring to FIGS. 17 and 18, in the case of FIG. 17 where the second data conductive layer DTL2 is located under the emission area, and thus the second data conductive layer DTL2 overlaps the emission area in the thickness direction, the flatness of the lower portion of the emission area may be deteriorated because the second data conductive layer DTL2 is located under the emission area in a linear shape. Accordingly, light generated in the light emitting layer is diffusely reflected, and a phenomenon of the reflective color bands of green, magenta and the like may clearly occur at the edges of emission areas. In this case, a color distribution appears to be wide, and a maximum value of a color difference ΔE00 is about 22.24.

In the case of FIG. 18 where the second data conductive layer DTL2 is not located under the emission area, and thus the second data conductive layer DTL2 does not overlap the emission area in the thickness direction, it may be possible to relatively improve the flatness of the lower portion of the emission area by arranging a dummy line of the second data conductive layer DTL2, which had overlapped the emission area in the thickness direction, to bypass the emission area without overlapping it. Accordingly, the diffused reflection of light generated in the light emitting layer may be suppressed, and the phenomenon of the reflective color band may be reduced at the edges of the emission areas as shown in FIG. 18. In this case, compared to the case of FIG. 17, because the color distribution appears to be narrow, and the maximum value of the color difference ΔE00 is lowered to about 14.11, it can be confirmed that the phenomenon of the reflective color band is reduced.

In concluding the detailed description, those skilled in the art will appreciate that many variations and modifications can be made to the example embodiments without substantially departing from the spirit and scope of embodiments according to the present disclosure. Therefore, the disclosed example embodiments of the invention are used in a generic and descriptive sense only and not for purposes of limitation.

What is claimed is:

1. A display device comprising:
a first emission area comprising a first light emitting element;
a first driving transistor configured to provide a driving current to the first light emitting element and having a first driving channel containing a first material;
a first transistor connected to the first driving transistor and having a first channel;
a second transistor connected to the first driving transistor and the first transistor and having a second channel;
a first data conductive layer comprising a connection electrode connected to the first transistor; and
a second data conductive layer comprising a first data line connected to the second transistor and a first driving voltage line connected to the first transistor through the connection electrode,
wherein the connection electrode overlaps the first emission area, and
wherein the first data line overlaps the connection electrode and does not overlap the first emission area.

2. The display device of claim 1, wherein the first data line and the first driving voltage line extend in a first direction, and
wherein the first data line and the first driving voltage line are spaced apart from each other in a second direction crossing the first direction.

3. The display device of claim 2, further comprising a second emission area spaced apart from the first emission area in a third direction crossing the first and second directions, and comprising a second light emitting element,
wherein the first driving voltage line does not overlap the first emission area, and
wherein the first driving voltage line overlaps the second emission area.

4. The display device of claim 3, further comprising a third transistor connected to the first driving transistor and having a third channel comprising a second material different from the first material,
wherein the third transistor overlaps the second emission area.

5. The display device of claim 4, wherein the first material contains polysilicon,
wherein the second material comprises an oxide semiconductor,
wherein the third transistor is on a different layer from the first driving transistor, the first transistor, and the second transistor, and
wherein the third transistor does not overlap the first emission area.

6. The display device of claim 3, further comprising:
a third emission area spaced apart from the first emission area in the first direction and comprising a third light emitting element;
a second driving transistor configured to provide a driving current to the third light emitting element and having a second driving channel containing the first material; and
a fourth transistor connected to the second driving transistor and having a fourth channel,
wherein the second data conductive layer further comprises a second data line connected to the fourth transistor,
wherein the second data line extends in the first direction,
wherein the second data line is spaced apart from the first data line in the second direction with the first emission area interposed therebetween, and
wherein the second data line does not overlap the first emission area.

7. The display device of claim 6, wherein the first light emitting element is configured to emit green light, the second light emitting element is configured to emit red light, and the third light emitting element is configured to emit blue light.

8. The display device of claim 6, wherein the first light emitting element is configured to emit red light or blue light, and the second light emitting element and the third light emitting element are configured to emit green light.

9. The display device of claim 3, wherein the connection electrode comprises a first portion having a larger size than the first emission area and a second portion protruding from the first portion and having a smaller size than the first portion,
wherein the first portion of the connection electrode completely overlaps the first emission area in a plan view, and
wherein the second portion of the connection electrode does not overlap the first emission area.

10. The display device of claim 9, wherein the first driving voltage line comprises a first portion having a larger size than the second emission area and a second portion protruding from the first portion and having a smaller size than the first portion,
wherein the first portion of the first driving voltage line completely overlaps the second emission area in the plan view, and
wherein the second portion of the first driving voltage line does not overlap the second emission area.

11. The display device of claim 10, wherein the first portion of the connection electrode and the first portion of the first driving voltage line have a plate shape.

12. The display device of claim 6, wherein the first data line comprises a first portion overlapping the connection electrode and a second portion not overlapping the connection electrode, and
wherein the first portion of the first data line comprises a curve.

13. The display device of claim 12, wherein the second data line comprises a first portion overlapping the connection electrode and a second portion not overlapping the connection electrode, and
wherein at least one of the first portion of the first data line or the first portion of the second data line comprises a curve.

14. The display device of claim 13, further comprising a sensing device which between the second portion of the first data line and the second portion of the second data line, and does not overlap the first data line and the second data line,
wherein the sensing device does not overlap the first emission area, the second emission area, and the third emission area.

15. The display device of claim 14, wherein the sensing device is between the first emission area and the third emission area.

16. A display device comprising:
a substrate;
a first transistor on the substrate, and comprising a first semiconductor layer containing a first material and a first gate electrode on the first semiconductor layer;
a first insulating layer between the first semiconductor layer and the first gate electrode, and covering the first semiconductor layer;
a second insulating layer on the first gate electrode, and covering the first gate electrode;
a first data conductive layer on the second insulating layer, and comprising a connection electrode connected to the first transistor;
a first via insulating layer on the first data conductive layer, and covering the connection electrode;
a second data conductive layer on the first via insulating layer, and comprising a data line configured to receive data voltages and a driving voltage line connected to the first transistor by the connection electrode;
a second via insulating layer on the second data conductive layer, and covering the second data conductive layer; and
a light emitting element layer on the second via insulating layer, and comprising a first light emitting element and a first emission area defined by a first opening of a pixel defining layer on the first light emitting element,
wherein the connection electrode overlaps the first emission area and the pixel defining layer, and
wherein the data line and the driving voltage line overlap the connection electrode, and do not overlap the first emission area.

17. The display device of claim 16, further comprising:
a third insulating layer on the second insulating layer;
a second semiconductor layer between the second insulating layer and the third insulating layer, and comprising a second material different from the first material;
a fourth insulating layer on the second semiconductor layer, and covering the second semiconductor layer; and
a second transistor comprising an upper gate electrode on the fourth insulating layer and a lower gate electrode on the second insulating layer with the second semiconductor layer interposed therebetween,
wherein the light emitting element layer further comprises a second light emitting element spaced apart from the first light emitting element and a second emission area defined by a second opening of a pixel defining layer on the second light emitting element, and
wherein the driving voltage line overlaps the second emission area.

18. The display device of claim 17, wherein the first material comprises polysilicon, and the second material contains an oxide semiconductor.

19. The display device of claim 17, further comprising:
a touch sensing unit on the pixel defining layer surrounding the first emission area and the second emission area, and comprising a touch insulating layer and a touch electrode; and
a light blocking member on the touch sensing unit and overlapping the pixel defining layer,
wherein the light blocking member overlaps the data line and the driving voltage line.

20. The display device of claim 19, further comprising a first color filter and a second color filter on the light blocking member,
wherein the first color filter overlaps the first emission area, and
wherein the second color filter overlaps the second emission area.
